(19) United States
(12) Patent Application Publication
(10) Pub. No.: US 2026/0171749 A1
(43) Pub. Date: Jun. 18, 2026

(54) SEMICONDUCTOR LASER ELEMENT

(71) Applicant: ROHM CO., LTD., Kyoto (JP)

(72) Inventor: Yuki HIROKAWA, Kyoto-shi (JP)

(73) Assignee: ROHM CO., LTD., Kyoto (JP)

(21) Appl. No.: 19/463,339

(22) Filed: Jan. 29, 2026

Related U.S. Application Data
(63) Continuation of application No. PCT/JP2024/026954, filed on Jul. 29, 2024.

(30) Foreign Application Priority Data
Aug. 7, 2023 (JP) 2023-128592

(51) Int. Cl. H01S 5/02; H01S 5/042; H01S 5/24

(52) U.S. Cl. CPC H01S 5/0202; H01S 5/0203; H01S 5/0207; H01S 5/04256; H01S 5/24

(57) ABSTRACT

A semiconductor laser element includes an element body which outputs laser light from a first end surface. The element body includes a first recessed part, and a second recessed part. The first recessed part includes a first inner surface that faces the same side as a first side surface, and first connection surface that connects the first inner surface and the first side surface. The second recessed part includes a second inner surface that faces the same side as a second side surface, and a second connection surface that connects the second inner surface and the second side surface. The first connection surface and the second connection surface each include an inclined surface which is inclined with respect to an element front surface at an angle differing from the that of first side surface and that of the second side surface.

### CROSS-REFERENCE TO RELATED APPLICATIONS

This application is a continuation of, and claims the benefit of priority from International Application No. PCT/JP2024/026954, filed on Jul. 29, 2024, which claims the benefit of priority from Japanese Patent Application No. 2023-128592, filed on Aug. 7, 2023, the entire contents of each of which are incorporated herein by reference.

### BACKGROUND

The present disclosure relates to a semiconductor laser element.

There is a disclosure of manufacturing of a semiconductor laser element from a laser bar by dividing a semiconductor wafer into laser bars and then forming separation grooves in the laser bars using laser cutting, a diamond cutter, or a dicer to cleave the laser bars into semiconductor laser elements (refer to, for example, WO2020/137146A).

### BRIEF DESCRIPTION OF DRAWINGS

FIG. 1 is a schematic perspective view of a semiconductor laser element in accordance with a first embodiment.

FIG. 2 is a schematic plan view of the semiconductor laser element shown in FIG. 1.

FIG. 3 is a schematic cross-sectional view of the semiconductor laser element taken along line F3-F3 in FIG. 2.

FIG. 4 is a schematic cross-sectional view of the semiconductor laser element taken along line F4-F4 in FIG. 2 enlarging a first recess and its surroundings.

FIG. 5 is a schematic side view of the first recess and its surroundings.

FIG. 6 is an enlarged view of the first recess shown in FIG. 5 showing a first end connection surface and its surroundings.

FIG. 7 is a schematic cross-sectional view of the semiconductor laser element taken along line F7-F7 in FIG. 6 enlarging the first end connection surface and its surroundings.

FIG. 8 is a schematic perspective view showing an exemplary manufacturing step of the semiconductor laser element in the first embodiment.

FIG. 9 is a schematic perspective view showing an exemplary manufacturing step following the step of FIG. 8.

FIG. 10 is a schematic perspective view showing an exemplary manufacturing step following the step of FIG. 9.

FIG. 11 is a schematic perspective view showing an exemplary manufacturing step following the step of FIG. 10.

FIG. 12 is a schematic plan view showing an exemplary manufacturing step following the step of FIG. 11.

FIG. 13 is a schematic cross-sectional view of laser bars taken along line F13-F13 in FIG. 12 enlarging a separation groove and its surroundings.

FIG. 14 is a schematic perspective view of a semiconductor laser element in accordance with a second embodiment.

FIG. 15 is a schematic bottom view of the semiconductor laser element shown in FIG. 14.

FIG. 16 is a schematic cross-sectional view of the semiconductor laser element taken along line F16-F16 in FIG. 15 enlarging a first recess and its surroundings.

FIG. 17 is a schematic cross-sectional view of a modified example of a semiconductor laser element enlarging a first recess and its surroundings.

FIG. 18 is a side view of a modified example of a semiconductor laser element as viewed from a first end surface.

### DETAILED DESCRIPTION

Embodiments of a semiconductor laser element according to the present disclosure will now be described with reference to the accompanying drawings. In the drawings, components may not be drawn to scale for simplicity and clarity of illustration. To facilitate understanding, hatching lines may not be shown in the cross-sectional drawings. The accompanying drawings merely illustrate exemplary embodiments of the present disclosure and are not intended to limit the present disclosure.

This detailed description includes exemplary embodiments of devices, systems, and methods in accordance with the present disclosure. Further, this detailed description is illustrative and is not intended to limit embodiments of the present disclosure or the application and use of the embodiments.

### First Embodiment

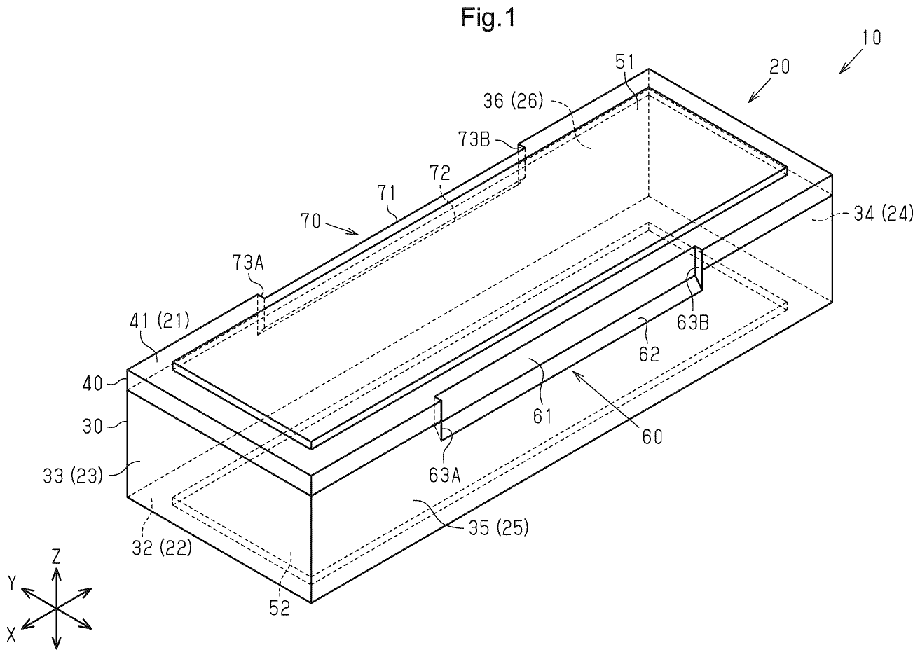

A first embodiment of a semiconductor laser element 10 will now be described with reference to FIGS. 1 to 13.

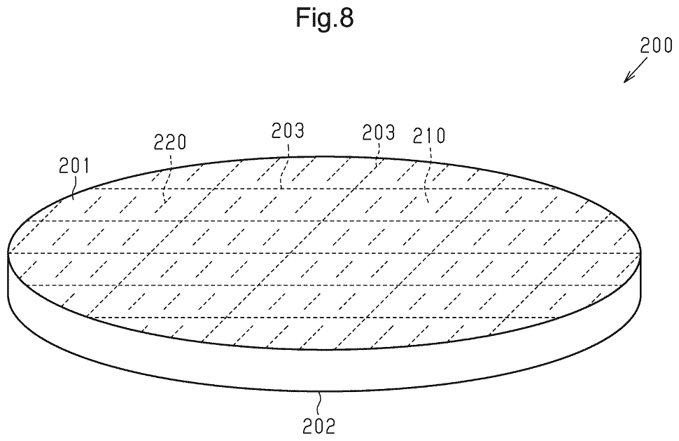

FIGS. 1 to 7 illustrate the structure of the semiconductor laser element 10. FIGS. 8 to 13 illustrate steps for manufacturing the semiconductor laser element 10.

### Overall Structure of Semiconductor Laser Element

The overall structure of the semiconductor laser element 10 will be described with reference to FIGS. 1 to 3.

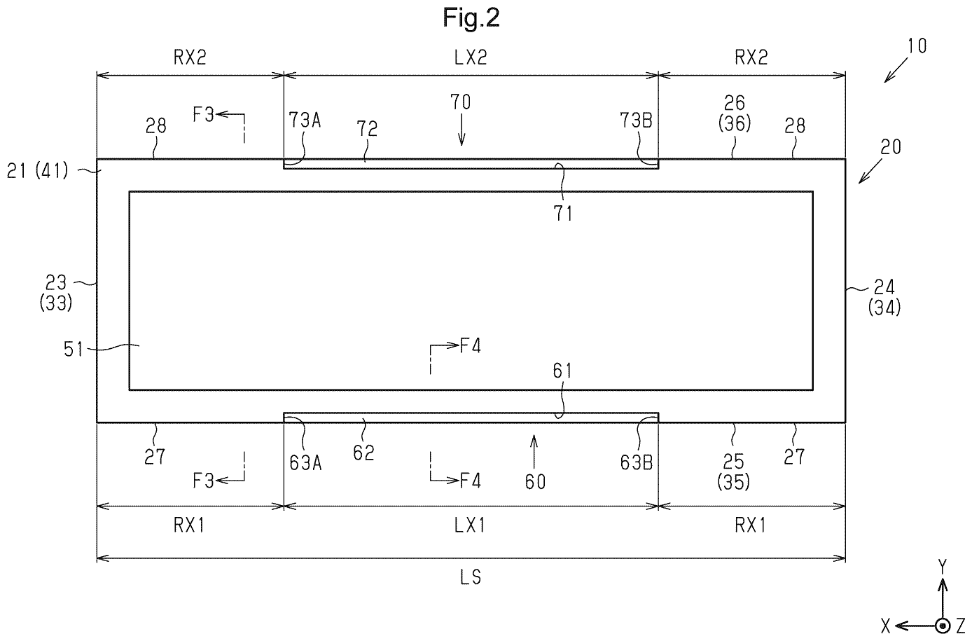

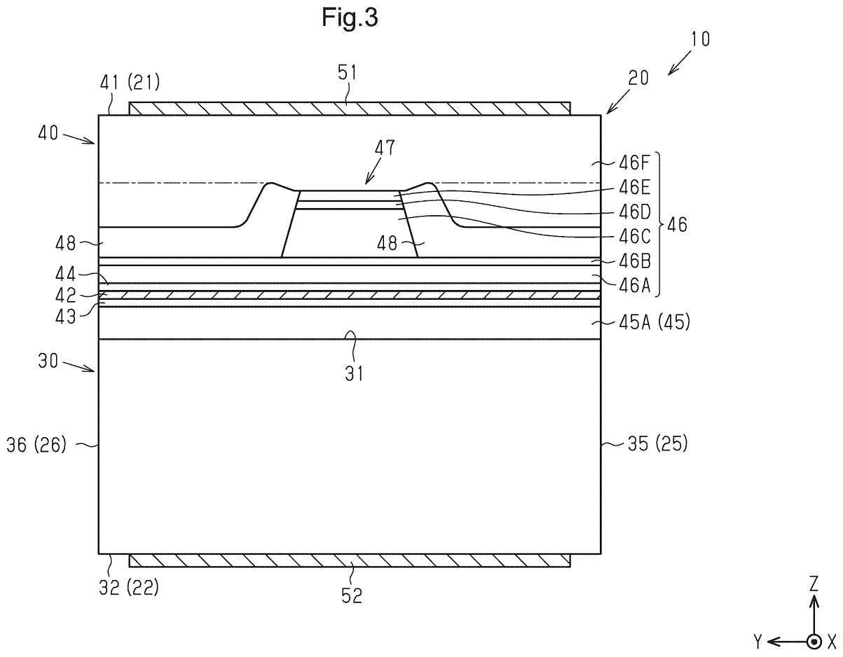

FIG. 1 is a schematic perspective view showing the structure of the semiconductor laser element 10. FIG. 2 is a schematic plan view showing the structure of the semiconductor laser element 10. FIG. 3 is a cross-sectional view of the semiconductor laser element 10 taken along line F3-F3 in FIG. 2 showing the internal structure of the semiconductor laser element 10. The term “plan view” used in the present disclosure refers to a view of the semiconductor laser element 10 in the Z-direction when the XYZ-axes are orthogonal to each other as shown in FIG. 1. In the present disclosure, the X-direction is an example of a “first direction.” The Y-direction is an example of a “second direction.”

As shown in FIG. 1, the semiconductor laser element 10 is an edge-emitting type laser diode and includes an element body 20, a front electrode 51, and a back electrode 52. The front electrode 51 and the back electrode 52 are arranged on the element body 20. In an example, the front electrode 51 includes an anode, and the back electrode 52 includes a cathode.

The element body 20 has the form of a rectangular box having a thickness in the Z-direction. Therefore, the term “plan view” refers to a view taken in the thickness direction of the element body 20. The element body 20 is rectangular in plan view, with long sides extending in the X-direction and short sides extending in the Y-direction.

The element body 20 includes an element front surface 21 and an element back surface 22 that face away from each other in the Z-direction, a first end surface 23 and a second end surface 24 that face away from each other in the X-direction in plan view, and a first side surface 25 and a second side surface 26 that face away from each other in the Y-direction in plan view. The thickness direction (the Z-direction) of the element body 20 also refer to a direction in which the element front surface 21 faces. The first end surface 23, the second end surface 24, the first side surface 25, and the second side surface 26 are arranged between the element front surface 21 and the element back surface 22 in the Z-direction and connect the element front surface 21 and the element back surface 22. The element body 20 is configured to emit light from the first end surface 23.

The front electrode 51 is formed on the element front surface 21. The front electrode 51 has the form of a rectangular plate having a thickness in the Z-direction. The front electrode 51 is rectangular in plan view, with long sides extending in the X-direction and short sides extending in the Y-direction. In the example shown in FIG. 1, in plan view, the front electrode 51 is slightly smaller than the element body 20. The front electrode 51 is formed of multiple electrode films having a layered structure. In an example, the front electrode 51 includes a first electrode film and a second electrode film formed on the first electrode film. The first electrode film is formed from, for example, a titanium (Ti)/gold (Au) alloy. The first electrode film is in contact with a front surface 41 (the element front surface 21) of a semiconductor layer 40. The second electrode film is formed of, for example, Au plating.

The back electrode 52 is formed on the element back surface 22. The back electrode 52 has the form of a rectangular plate having a thickness in the Z-direction. The back electrode 52 is rectangular in plan view, with long sides extending in the X-direction and short sides extending in the Y-direction. In the example shown in FIG. 1, in plan view, the back electrode 52 is slightly smaller than the element body 20. That is, the back electrode 52 is the same in size as the front electrode 51. The back electrode 52 is formed of multiple electrode films having a layered structure. The back electrode 52 is formed from, for example, a gold-germanium-nickel (AuGeNi)/Ti/Au alloy. The back electrode 52 is in ohmic contact with a semiconductor substrate 30.

The element body 20 includes the semiconductor substrate 30 and the semiconductor layer 40 arranged on the semiconductor substrate 30.

The semiconductor substrate 30 has the form of a rectangular plate having a thickness in the Z-direction. The semiconductor substrate 30 is rectangular in plan view, with long sides extending in the X-direction and short sides extending in the Y-direction.

As shown in FIGS. 1 and 3, the semiconductor substrate 30 includes a substrate front surface 31 and a substrate back surface 32 that face away from each other in the Z-direction, and a first substrate end surface 33, a second substrate end surface 34, a first substrate side surface 35, and a second substrate side surface 36 arranged between the substrate front surface 31 and the substrate back surface 32 in the Z-direction and connecting the substrate front surface 31 and the substrate back surface 32. The substrate front surface 31 and the element front surface 21 face in the same direction. The substrate back surface 32 and the element back surface 22 face in the same direction. The substrate back surface 32 includes the element back surface 22. The first substrate end surface 33 and the second substrate end surface 34 include two end surfaces of the semiconductor substrate 30 in the X-direction. That is, the first substrate end surface 33 and the second substrate end surface 34 face away from each other in the X-direction. The first substrate side surface 35 and the second substrate side surface 36 include two end surfaces of the semiconductor substrate 30 in the Y-direction. That is, the first substrate side surface 35 and the second substrate side surface 36 face away from each other in the Y-direction. Thus, the first substrate end surface 33 and the first end surface 23 face in the same direction. The second substrate end surface 34 and the second end surface 24 face in the same direction. The first substrate side surface 35 and the first side surface 25 face in the same direction. The second substrate side surface 36 and the second side surface 26 face in the same direction. In an example, the first substrate end surface 33 includes a portion of the first end surface 23 in the Z-direction. The second substrate end surface 34 includes a portion of the second end surface 24 in the Z-direction. The first substrate side surface 35 includes a portion of the first side surface 25 in the Z-direction. The second substrate side surface 36 includes a portion of the second side surface 26 in the Z-direction. In FIG. 3, the semiconductor layer 40 is drawn to have substantially the same thickness as the semiconductor substrate 30 so that each component of the semiconductor layer 40 is shown. However, the actual thickness of the semiconductor layer 40 is smaller than the thickness of the semiconductor substrate 30.

The semiconductor substrate 30 includes, for example, an n-type semiconductor substrate (n-GaAs substrate) containing gallium-arsenic (GaAs). The semiconductor substrate 30 includes, for example, at least one of silicon (Si), tellurium (Te), and selenium (Se) as an n-type impurity. In the first embodiment, the first substrate side surface 35 and the second substrate side surface 36 each have an angle of 90° relative to the substrate front surface 31. Taking into consideration manufacturing errors of the semiconductor substrate 30, the angle of each of the first substrate side surface 35 and the second substrate side surface 36 relative to the substrate front surface 31 being 90° includes angles of the first substrate side surface 35 and the second substrate side surface 36 relative to the substrate front surface 31 being greater than or equal to 85° and less than or equal to 95°. In other words, the semiconductor substrate 30 has an off-angle of 0°. That is, the semiconductor substrate 30 is an on-axis substrate.

The substrate front surface 31 of the semiconductor substrate 30 has a (100) plane orientation. The semiconductor layer 40 is formed on the substrate front surface 31. The semiconductor layer 40 includes the front surface 41 of the element front surface 21. The semiconductor layer 40 is epitaxially grown on the semiconductor substrate 30. The semiconductor layer 40 has a semiconductor layer laminated structure in which multiple semiconductor layers are stacked in the Z-direction.

The first substrate end surface 33, the second substrate end surface 34, the first substrate side surface 35, and the second substrate side surface 36 of the semiconductor substrate 30 each have a (110) plane orientation. When the semiconductor substrate 30 is formed of a semiconductor substrate containing GaAs, the (110) plane of the semiconductor substrate 30 has a high cleavability. In addition, the first substrate end surface 33 and the second substrate end surface 34 of the semiconductor substrate 30 cleaves more easily than the first substrate side surface 35 and the second substrate side surface 36.

As shown in FIG. 3, the semiconductor layer 40 includes multiple semiconductor layers, namely, an active layer 42, an n-side guide layer 43, a p-side guide layer 44, an n-type semiconductor layer 45, and a p-type semiconductor layer 46.

The n-side guide layer 43 is arranged between the n-type semiconductor layer 45 and the active layer 42, and the p-side guide layer 44 is arranged between the active layer 42 and the p-type semiconductor layer 46. Thus, a double heterojunction is formed. Electrons are injected into the active layer 42 from the n-type semiconductor layer 45 through the n-side guide layer 43. Holes are injected into the active layer 42 from the p-type semiconductor layer 46 through the p-side guide layer 44. When the electrons and the holes are recombined in the active layer 42, laser light is generated in the active layer 42.

The n-type semiconductor layer 45 includes an n-type cladding layer 45A formed on the semiconductor substrate 30. The n-type cladding layer 45A is arranged closer to the semiconductor substrate 30 than the active layer 42 is. The n-type cladding layer 45A is formed from a material containing, for example, aluminum gallium arsenide (AlGaAs). The n-type cladding layer 45A has a thickness of, for example, greater than or equal to 20000 angstroms and less than or equal to 35000 angstroms. The n-type cladding layer 45A is formed of, for example, an AlₓGa₍₁₋ₓ₎As layer, where 0≤x≤1.

The p-type semiconductor layer 46 includes a first p-type cladding layer 46A, a first p-type etching stop layer 46B, a second p-type cladding layer 46C, a second p-type etching stop layer 46D, a p-type cap layer 46E, and a p-type contact layer 46F that are stacked on the p-side guide layer 44. The first p-type cladding layer 46A and the second p-type cladding layer 46C are each an example of “p-type cladding layer.”

The first p-type cladding layer 46A and the second p-type cladding layer 46C are located at a side of the active layer 42 opposite from the n-type cladding layer 45A. The first p-type cladding layer 46A and the second p-type cladding layer 46C are formed from a material containing, for example, AlGaAs. The first p-type cladding layer 46A has a thickness of, for example, greater than or equal to 1000 angstroms and less than or equal to 2000 angstroms. The second p-type cladding layer 46C has a thickness of, for example, greater than or equal to 8000 angstroms and less than or equal to 12000 angstroms. Therefore, the second p-type cladding layer 46C is greater in thickness than the first p-type cladding layer 46A. The first p-type cladding layer 46A and the second p-type cladding layer 46C are formed of, for example, an AlₓGa₍₁₋ₓ₎As layer, where 0≤x≤1.

The first p-type etching stop layer 46B and the second p-type etching stop layer 46D are formed from a material containing, for example, indium gallium phosphide (InGaP). The first p-type etching stop layer 46B and the second p-type etching stop layer 46D are each smaller in thickness than each of the first p-type cladding layer 46A and the second p-type cladding layer 46C. The first p-type etching stop layer 46B has a thickness of, for example, greater than or equal to 50 angstroms and less than or equal to 300 angstroms. The second p-type etching stop layer 46D has a thickness of, for example, greater than or equal to 50 angstroms and less than or equal to 300 angstroms.

The p-type cap layer 46E is formed from a material containing, for example, GaAs. In an example, the p-type cap layer 46E is greater in thickness than each of the first p-type etching stop layer 46B and the second p-type etching stop layer 46D and is smaller in thickness than each of the first p-type cladding layer 46A and the second p-type cladding layer 46C. The p-type cap layer 46E has a thickness of, for example, greater than or equal to 1000 angstroms and less than or equal to 3000 angstroms.

The p-type contact layer 46F is a low-resistance layer configured to be in ohmic contact with the front electrode 51. The p-type contact layer 46F is, for example, a p-type semiconductor layer in which beryllium (Be) is injected into GaAs as a p-type dopant. The p-type contact layer 46F is greater in thickness than each of the first p-type cladding layer 46A, the first p-type etching stop layer 46B, the second p-type cladding layer 46C, the second p-type etching stop layer 46D, and the p-type cap layer 46E. The p-type contact layer 46F has a thickness of, for example, greater than or equal to 30000 angstroms and less than or equal to 60000 angstroms.

The n-type cladding layer 45A, the first p-type cladding layer 46A, and the second p-type cladding layer 46C are configured so as to produce an effect of confining the carriers (electrons and holes) in the active layer 42 and an effect of confining laser light from the active layer 42 among the n-type cladding layer 45A, the first p-type cladding layer 46A, and the second p-type cladding layer 46C. The n-type cladding layer 45A is, for example, an n-type semiconductor layer in which silicon (Si) is injected into AlGaAs as an n-type dopant. The first p-type cladding layer 46A and the second p-type cladding layer 46C are each, for example, a p-type semiconductor layer in which Be is injected into AlGaAs as a p-type dopant.

The n-type cladding layer 45A has a larger band gap than the n-side guide layer 43. The first p-type cladding layer 46A and the second p-type cladding layer 46C each have a larger band gap than the p-side guide layer 44. This improves the effect of confining carriers in the active layer 42 and the effect of confining laser light from the active layer 42 among the n-type cladding layer 45A, the first p-type cladding layer 46A, and the second p-type cladding layer 46C, thereby increasing the efficiency of the semiconductor laser element 10.

The n-side guide layer 43 and the p-side guide layer 44 are each formed from a material containing AlGaAs. The n-side guide layer 43 and the p-side guide layer 44 each have a thickness of, for example, greater than or equal to 200 angstroms and less than or equal to 500 angstroms. The n-side guide layer 43 is formed on the n-type semiconductor layer 45. The p-side guide layer 44 is formed on the active layer 42. The n-side guide layer 43 and the p-side guide layer 44 are each formed of, for example, an AlₓGa₍₁₋ₓ₎As layer, where 0≤x≤1.

The active layer 42 has the multiple-quantum well (MQW) structure. The active layer 42 is used to generate laser light by recombination of electrons and holes and to amplify the laser light. The active layer 42 is formed by, for example, repeatedly alternately stacking a quantum well layer formed of an undoped GaAsP layer and a barrier layer formed of an undoped InAlGaAs layer in a number of periods.

In the p-type semiconductor layer 46, each of the second p-type cladding layer 46C, the second p-type etching stop layer 46D, and the p-type cap layer 46E are partially removed to form a ridge 47. In an example, etching is performed to partially remove the second p-type cladding layer 46C, the second p-type etching stop layer 46D, and the p-type cap layer 46E. As a result, a trapezoidal (mesa-shaped) ridge 47 is formed as shown in the cross section in FIG. 3.

A current confinement layer 48 is formed on a side surface of the ridge 47. In an example, the current confinement layer 48 covers a side surface of the p-type cap layer 46E, a side surface of the second p-type etching stop layer 46D, an exposed surface of the second p-type cladding layer 46C, and an exposed surface of the first p-type etching stop layer 46B. The p-type contact layer 46F covers the current confinement layer 48 and an exposed surface of the p-type cap layer 46E.

The semiconductor laser element 10 includes a Fabry-Perot resonator in which the n-side guide layer 43, the active layer 42, and the p-side guide layer 44 cause the first end surface 23 and the second end surface 24 (refer to FIG. 1) to serve as resonator end surfaces. More specifically, while reciprocating between the first end surface 23 and the second end surface 24, the laser light generated in the active layer 42 is amplified by stimulated emission. The amplified laser light is partially emitted from the first end surface 23 and the second end surface 24 as laser light. In the first embodiment, an end-surface coating (not shown) is formed on each of the first end surface 23 and the second end surface 24. The end-surface coating may include an insulative reflection coating. The end-surface coating may include an insulative anti-reflection coating (AR coating). The end-surface coating including the reflection coating may have an adjusted reflectance. In an example, reflection coatings may be formed by firing so that the first end surface 23 mainly emits laser light, while the second end surface 24 hardly emits laser light.

### Structure of Side Surface of Semiconductor Laser Element

The structure of the side surface of the semiconductor laser element 10 will be described with reference to FIGS. 1 to 7.

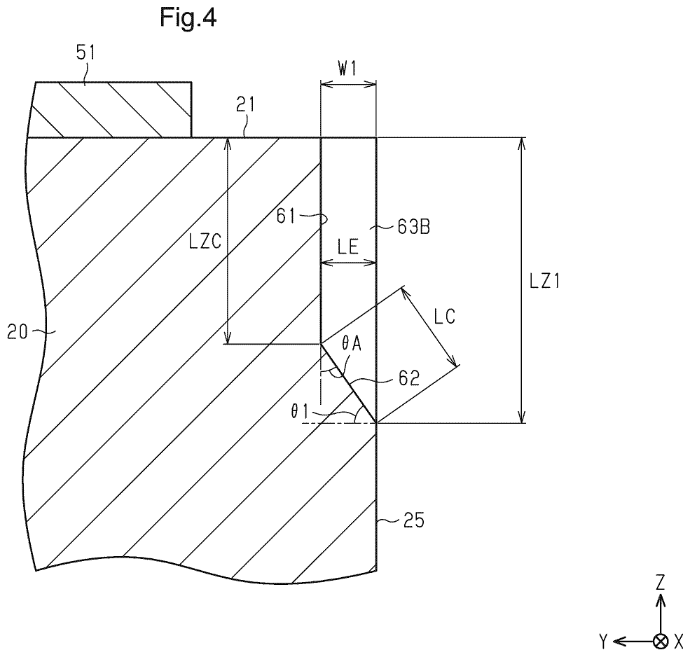

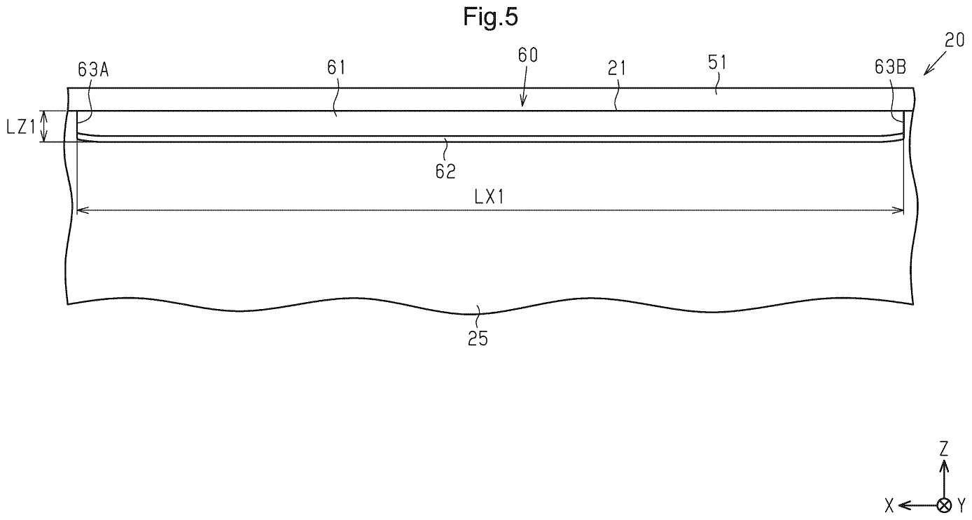

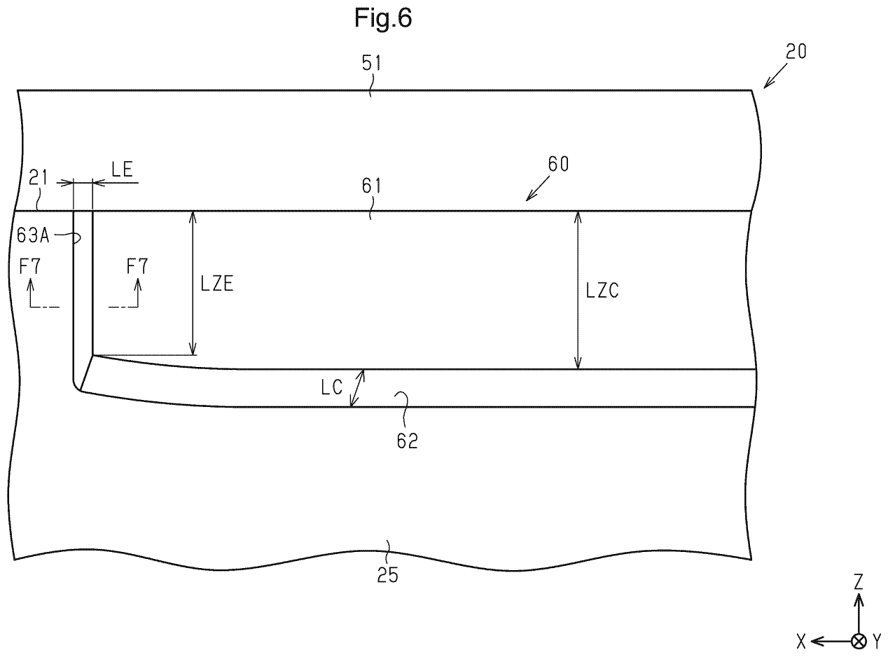

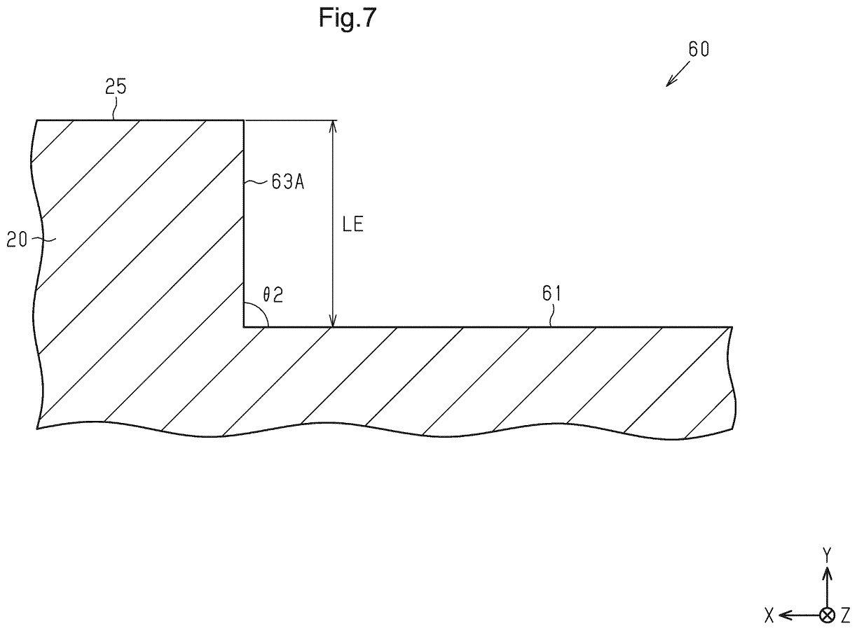

FIG. 4 is a cross-sectional view of the structure of the semiconductor laser element 10 taken along line F4-F4 in FIG. 2, showing an enlarged partial cross section of the element front surface 21 and the first side surface 25 of the element body 20. FIG. 5 is an enlarged view of a first recess 60, which will be described later. FIG. 6 is an enlarged partial view of the first recess 60 in FIG. 5. FIG. 7 is a cross-sectional view of the first recess 60 taken along line F7-F7 in FIG. 6.

As shown in FIGS. 1 and 2, the element body 20 includes the first recess 60 and a second recess 70. The first recess 60 is arranged between the first side surface 25 and the element front surface 21 of the element body 20. The first recess 60 is recessed into the element body 20. The first recess 60 is open in a direction in which the element front surface 21 faces and a direction in which the first side surface 25 faces. The second recess 70 is arranged between the second side surface 26 and the element front surface 21 of the element body 20. The second recess 70 is recessed into the element body 20. The second recess 70 is open in the direction in which the element front surface 21 faces and a direction in which the second side surface 26 faces. The first recess 60 and the second recess 70 are formed in a portion of the element body 20 located toward the element front surface 21 in the Z-direction including the element front surface 21. The first recess 60 and the second recess 70 extend from the semiconductor layer 40 to the semiconductor substrate 30. More specifically, the first recess 60 and the second recess 70 extend through the entirety of the semiconductor layer 40 in the Z-direction. The first recess 60 and the second recess 70 are formed in a portion of the semiconductor substrate 30 located toward the semiconductor layer 40 in the Z-direction.

The first recess 60 includes a first inner side surface 61 facing in the same direction as the first side surface 25 and a first connection surface 62 connecting the first inner side surface 61 and the first side surface 25.

The first inner side surface 61 is located closer, in the Y-direction, to the second side surface 26 than the first side surface 25 is. The first inner side surface 61 is connected to the element front surface 21. The first inner side surface 61 extends through the semiconductor layer 40 (refer to FIG. 3) in the Z-direction. The first inner side surface 61 is formed in a portion of the semiconductor substrate 30 located toward the semiconductor layer 40 in the Z-direction. In an example, the first inner side surface 61 is parallel to the first side surface 25.

The first connection surface 62 is arranged closer to the element back surface 22 than the first inner side surface 61 is. That is, the first connection surface 62 is arranged closer to the element back surface 22 than the semiconductor layer 40 is. In other words, the semiconductor substrate 30 (refer to FIG. 3) includes the first connection surface 62. The first connection surface 62 is connected to one of the opposite edges of the first inner side surface 61 in the Z-direction located closer to the element back surface 22. In an example, the first connection surface 62 is connected to the entirety of the edge of the first inner side surface 61 in the X-direction.

The first connection surface 62 includes an inclined surface inclined relative to the element front surface 21 at an angle differing from those of the first side surface 25 and the second side surface 26. More specifically, the first connection surface 62 is inclined toward the first side surface 25 as the first connection surface 62 extends from the first inner side surface 61 toward the element back surface 22 in the Z-direction.

As shown in FIG. 4, the first connection surface 62 has an angle θ1 that is greater than or equal to 45° and less than or equal to 65° relative to the element front surface 21. Preferably, the angle θ1 is greater than or equal to 50° and less than or equal to 60°. The first connection surface 62 has a length LC in the inclination direction. The first inner side surface 61 has a length LZC in the Z-direction. The length LC is less than the length LZC. The first inner side surface 61 includes an end in the X-direction having a length LZE (refer to FIG. 6) in the Z-direction. In an example, the length LC is less than the length LZE. In an example, the length LC is greater than or equal to 2 μm and less than or equal to 8 μm.

In a direction (in the first embodiment, the Y-direction) orthogonal to the first side surface 25, a distance W1 between the first side surface 25 and the first inner side surface 61 is less than a length LX1 (refer to FIG. 2) of the first recess 60 in the X-direction. In an example, the distance W1 is less than a length LZ1 of the first recess 60 in the Z-direction. In an example, the distance W1 is less than the length LZC of the first inner side surface 61 in the Z-direction. In an example, the distance W1 is less than the length LC of the first connection surface 62 in the inclination direction. In the example shown in FIG. 4, the distance W1 is greater than or equal to 1 μm and less than or equal to 5 μm.

As shown in FIG. 5, opposite end portions of the first connection surface 62 in the X-direction are inclined toward the element front surface 21 as the edges in the X-direction become closer. As shown in FIG. 6, one of the opposite end portions of the first connection surface 62 in the X-direction located closer to the first end surface 23 (refer to FIG. 2) is curved toward the element front surface 21 as the edge of the first connection surface 62 in the X-direction becomes closer. Therefore, the end portions of the first inner side surface 61 in the X-direction have a length LZE in the Z-direction, and the length LZE is less than the length LZC, in the Z-direction, of a portion of the first inner side surface 61 located closer to the center than the end portions in the X-direction. One of the opposite end portions of the first connection surface 62 in the X-direction located closer to the second end surface 24 (refer to FIG. 2) may have the same structure as one of the opposite end portions of the first connection surface 62 in the X-direction located closer to the first end surface 23.

As shown in FIG. 5, the first recess 60 includes first end connection surfaces 63A and 63B arranged on opposite ends in the X-direction. The first end connection surface 63A connects the first side surface 25 to one of the opposite ends of the first inner side surface 61 in the X-direction located closer to the first end surface 23 (refer to FIG. 2). The first end connection surface 63B connects the first side surface 25 to one of the opposite ends of the first inner side surface 61 in the X-direction located closer to the second end surface 24 (refer to FIG. 2).

As shown in FIG. 6, the first end connection surface 63A connects the element front surface 21 and the first connection surface 62 in the Z-direction. In an example, the first end connection surface 63A extends in the Z-direction. In an example, the first end connection surface 63A is orthogonal to the element front surface 21.

As shown in FIG. 7, an angle θ2 of the first end connection surface 63A relative to the first inner side surface 61 is greater than an angle θA (refer to FIG. 4) of the first connection surface 62 relative to the first inner side surface 61. In an example, the angle θ2 is greater than or equal to 85° and less than or equal to 95°. In an example, the angle θ2 is greater than or equal to 87° and less than or equal to 93°. In an example, the angle θ2 is greater than or equal to 88° and less than or equal to 92°. In an example, the angle θ2 is greater than or equal to 89° and less than or equal to 91°. In the example shown in FIG. 7, the angle θ2 is 90°.

As shown in FIGS. 6 and 7, the first end connection surface 63A has a length LE between the first inner side surface 61 and the first side surface 25, and the length LE is less than the length LC (refer to FIG. 6) of the first connection surface 62 in the inclination direction. In an example, the length LE is greater than or equal to 1 μm and less than or equal to 5 μm.

The first end connection surface 63B has the same structure as the first end connection surface 63A. Therefore, the angle of the first end connection surface 63B relative to the first inner side surface 61 is equal to the angle θ2. The length of the first end connection surface 63B between the first inner side surface 61 and the first side surface 25 is equal to the length LE.

As shown in FIG. 2, the second recess 70 includes a second inner side surface 71 facing in the same direction as the second side surface 26 and a connection surface 72 connecting the second inner side surface 71 and the second side surface 26. The second connection surface 72 includes an inclined surface inclined relative to the element front surface 21 at an angle differing from those of the first side surface 25 and the second side surface 26. The second recess 70 includes second end connection surfaces 73A and 73B arranged on opposite ends in the X-direction. The second end connection surface 73A connects the second side surface 26 to one of the opposite ends of the second inner side surface 71 in the X-direction located closer to the first end surface 23. The second end connection surface 73B connects the second side surface 26 to one of the opposite ends of the second inner side surface 71 in the X-direction located closer to the second end surface 24.

The second recess 70 and the first recess 60 are identical in shape and size. Therefore, the angle of the second connection surface 72 relative to the element front surface 21 is equal to the angle θ1 of the first connection surface 62 relative to the element front surface 21. More specifically, the angle of the second connection surface 72 relative to the element front surface 21 is greater than or equal to 50° and less than or equal to 60°. Preferably, the angle of the second connection surface 72 relative to the element front surface 21 is greater than or equal to 53° and less than or equal to 57°. In a direction (in the first embodiment, the Y-direction) orthogonal to the second side surface 26, the distance between the second side surface 26 and the second inner side surface 71 is equal to the distance W1. More specifically, in the direction orthogonal to the second side surface 26, the distance between the second side surface 26 and the second inner side surface 71 is greater than or equal to 1 μm and less than or equal to 5 μm. The angle of each of the second end connection surfaces 73A and 73B relative to the second inner side surface 71 is equal to the angle θ2 of the first end connection surface 63A relative to the first inner side surface 61. Thus, the angle of each of the second end connection surfaces 73A and 73B relative to the second inner side surface 71 is greater than the angle of the second connection surface 72 relative to the second inner side surface 71. The angle of each of the second end connection surfaces 73A and 73B relative to the second inner side surface 71 may be, for example, greater than or equal to 85° and less than or equal to 95°, greater than or equal to 87° and less than or equal to 93°, greater than or equal to 88° and less than or equal to 92°, or greater than or equal to 89° and less than or equal to 91°. The length of each of the second end connection surfaces 73A and 73B between the second inner side surface 71 and the second side surface 26 is equal to the length LE of the first end connection surface 63A between the first inner side surface 61 and the first side surface 25. Therefore, the length of each of the second end connection surfaces 73A and 73B between the second inner side surface 71 and the second side surface 26 is less than the length of the second connection surface 72 in the inclination direction. The length of each of the second end connection surfaces 73A and 73B between the second inner side surface 71 and the second side surface 26 may be, for example, greater than or equal to 1 μm and less than or equal to 5 μm.

As shown in FIGS. 1 and 2, the first recess 60 and the second recess 70 are partially arranged in the element body 20 in the X-direction.

The element body 20 includes first regions 27 and second regions 28 arranged at opposite ends in the X-direction. The first regions 27 are formed at opposite ends of the first side surface 25 of the element body 20 in the X-direction. The second regions 28 are formed at opposite ends of the second side surface 26 of the element body 20 in the X-direction. The first recess 60 is arranged in the element body 20 between the first regions 27, which are formed at opposite ends in the X-direction, in the X-direction. The second recess 70 is arranged in the element body 20 between the second regions 28, which are formed at opposite ends in the X-direction, in the X-direction. In the example shown in FIGS. 1 and 2, a single first recess 60 is arranged in the element body 20 between the first regions 27, which are formed at opposite ends in the X-direction, in the X-direction. Also, a single second recess 70 is arranged in the element body 20 between the second regions 28, which are formed at opposite ends in the X-direction, in the X-direction. Thus, the first recess 60 and the second recess 70 are formed in the element body 20 at positions separated from the first end surface 23 and the second end surface 24 in the X-direction.

The lengths LX1 and LX2 of the first recess 60 and the second recess 70 in the X-direction are respectively greater than a length RX1 of each first region 27 in the X-direction and a length RX2 of each second region 28 in the X-direction. The lengths LX1 and LX2 are each greater than the total length (RX1+RX2) of the length RX1 and the length RX2. That is, the lengths LX1 and LX2 are greater than ½ of a length LS of the element body 20 in the X-direction. In an example, the length LX1 of the first recess 60 in the X-direction is equal to the length LX2 of the second recess 70 in the X-direction.

In the example shown in FIGS. 1 and 2, the two first regions 27 are equal in the length RX1 in the X-direction. The two second regions 28 are equal in length RX2 in the X-direction. The length RX1 is equal to the length RX2. The lengths RX1 and RX2 may be changed in any manner. In an example, the two first regions 27 may differ from each other in the length RX1 in the X-direction. In an example, the two second regions 28 may differ from each other in the length RX2 in the X-direction. In an example, the length RX1 may differ from the length RX2.

A ratio (LX1/LS) of the length LX1 of the first recess 60 in the X-direction to the length LS of the element body 20 in the X-direction and a ratio (LX2/LS) of the length LX2 of the second recess 70 in the X-direction to the length LS of the element body 20 in the X-direction are each greater than or equal to ⅝ and less than or equal to ⅞. In an example, the ratio (LX1/LS) and the ratio (LX2/LS) may each be greater than or equal to 4/6 and less than or equal to ⅚.

In the example shown in FIG. 2, the lengths LX1 and LX2 of the first recess 60 and the second recess 70 in the X-direction are each approximately 400 μm. The length RX1 of the first region 27 in the X-direction is approximately 100 μm. The length RX2 of the second region 28 in the X-direction is approximately 100 μm. Thus, the length LS of the element body 20 in the X-direction is approximately 600 μm. Therefore, the ratio (LX1/LS) of the length LX1 of the first recess 60 in the X-direction to the length LS of the element body 20 in the X-direction and the ratio (LX2/LS) of the length LX2 of the second recess 70 in the X-direction to the length LS of the element body 20 in the X-direction are each ⅔.

The length LZ1 of the first recess 60 in the Z-direction is less than the length LX1 of the first recess 60 in the X-direction. The length LZ1 is defined by the distance in the Z-direction from the element front surface 21 to the boundary between the first connection surface 62 and the first side surface 25. The boundary between the first connection surface 62 and the first side surface 25 is where the first connection surface 62 is connected to the first side surface 25 in the Z-direction.

The length of the second recess 70 in the Z-direction is less than the length LX2 of the second recess 70 in the X-direction. The length of the second recess 70 in the Z-direction is defined by the distance in the Z-direction from the element front surface 21 to the boundary between the second connection surface 72 and the second side surface 26. The boundary between the second connection surface 72 and the second side surface 26 is where the second connection surface 72 is connected to the second side surface 26 in the Z-direction.

### Method for Manufacturing Semiconductor Laser Element

With reference to FIGS. 8 to 13, a method for manufacturing the semiconductor laser element 10 will be described. A process that divides a semiconductor wafer 200 to manufacture multiple semiconductor laser elements 10 will be described below.

FIG. 8 a schematic perspective view showing the structure of the semiconductor wafer 200.

As shown in FIG. 8, the method for manufacturing the semiconductor laser element 10 includes a step of preparing the semiconductor wafer 200. The semiconductor wafer 200 is formed from GaAs. The semiconductor wafer 200 includes a wafer including multiple semiconductor substrates 30 (refer to FIG. 1) and a semiconductor layer laminated structure forming the semiconductor layer 40 (refer to FIG. 1) on each semiconductor substrate 30. The semiconductor wafer 200 includes a wafer front surface 201 and a wafer back surface 202 facing away from each other in the Z-direction. The wafer front surface 201 has a (100) plane. Although not shown, multiple front electrodes 51 (refer to FIG. 1) are formed on the wafer front surface 201. Also, multiple back electrodes 52 (refer to FIG. 1) are formed on the wafer back surface 202.

The semiconductor wafer 200 includes laser bars (LD bars) 210 including multiple individual elements. Each laser bar 210 is formed in a rectangular region defined by imaginary cutting lines 203 on the semiconductor wafer 200. Each individual element includes a semiconductor laser element 10 (refer to FIG. 1). The laser bar 210 includes multiple semiconductor laser elements 10. The laser bar 210 may be referred to as a bar-shaped body or a base substrate.

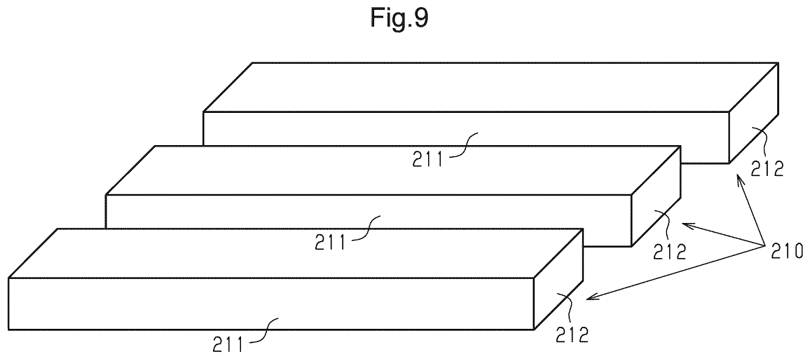

As shown in FIG. 8, the method for manufacturing the semiconductor laser element 10 includes a step of dividing the semiconductor wafer 200 along the cutting lines 203. In an example, a diamond cutter is used to mark the semiconductor wafer 200 along the cutting lines 203. Subsequently, force is applied to the wafer back surface 202 of the semiconductor wafer 200 to divide the semiconductor wafer 200 into pieces. As shown in FIG. 9, the step forms bar-shaped laser bars 210 each having long sides and short sides. FIG. 9 is a schematic perspective view of the structure of three laser bars 210. In FIG. 9, the front electrode 51, the back electrode 52, and separation grooves 220 are not shown. The separation grooves 220 will be described later. Alternatively, a plate-shaped substrate including laser bars 210 may be cut out from the semiconductor wafer 200, and then the plate-shaped substrate is cleaved to form the laser bars 210. The plate-shaped substrate may be cut by dicing, scribe, or laser cutting.

Each laser bar 210 includes a side surface 211 in the longitudinal direction, defining the first end surface 23 (the second end surface 24) of the semiconductor laser element 10 shown in FIG. 1. The laser bar 210 includes a side surface 212 in the transverse direction, defining the first side surface 25 (the second side surface 26) of the semiconductor laser element 10 shown in FIG. 1.

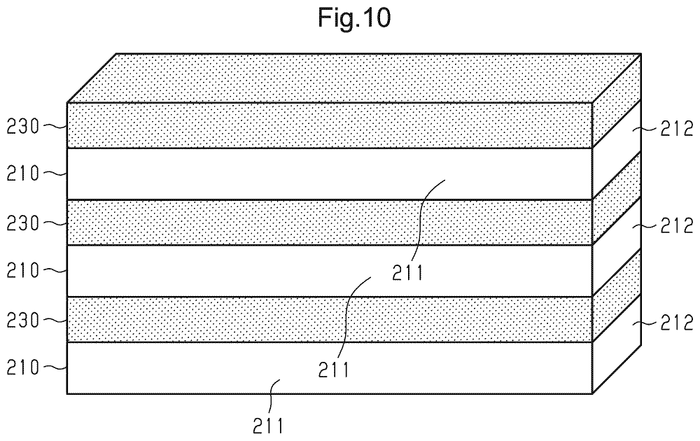

FIG. 10 shows a stacked structure of the laser bars 210 and separators 230.

As shown in FIG. 10, the method for manufacturing the semiconductor laser element 10 includes a step of alternately stacking the laser bars 210 and the separators 230 one at a time, and to form an end-surface coating. The end-surface coating may include an insulative reflection coating. The end-surface coating may include an insulative anti-reflection coating (AR coating). The end-surface coating including the reflection coating may have an adjusted reflectance. In an example, reflection coatings may be formed by firing so that the side surface 211 forming the first end surface 23 mainly emits laser light, while the side surface 211 forming the second end surface 24 hardly emits laser light.

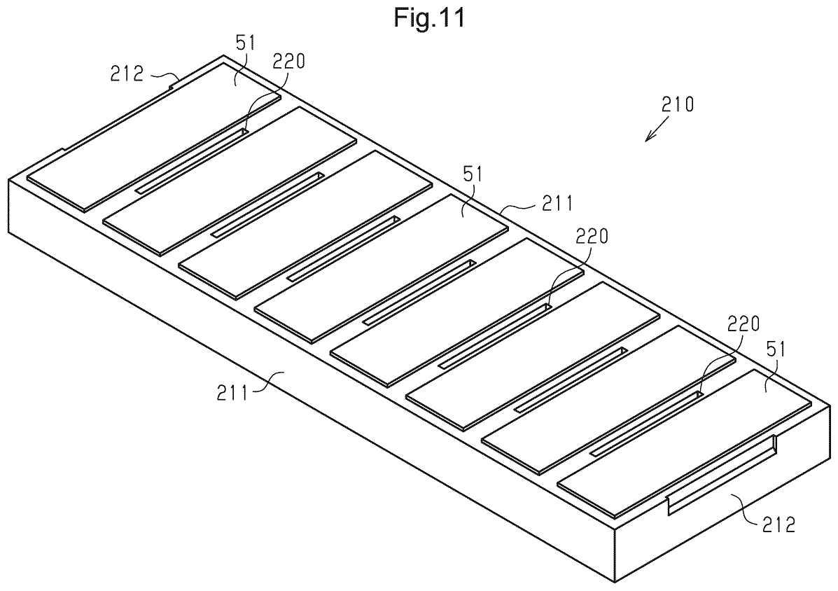

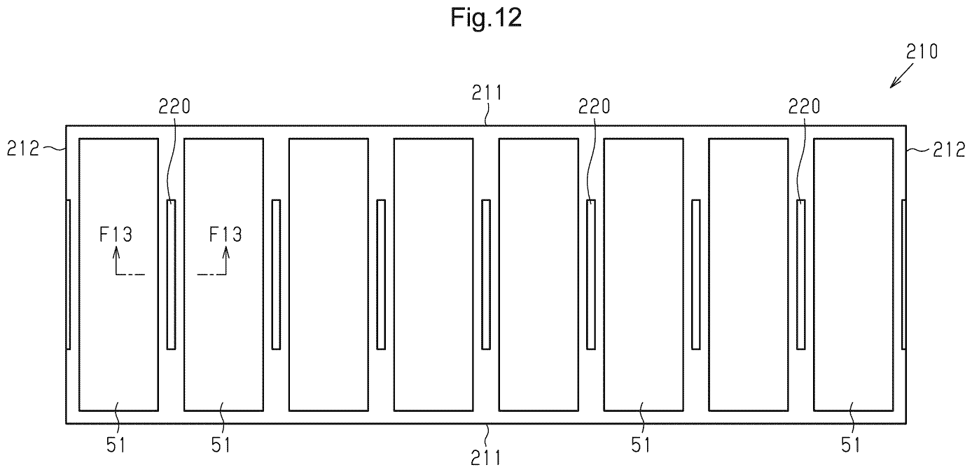

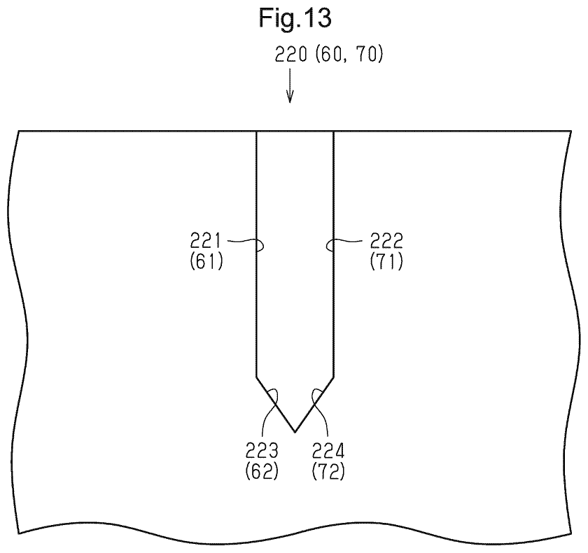

FIG. 11 is a perspective view showing the structure of a single laser bar 210. FIG. 12 is a plan view showing the structure of the single laser bar. FIG. 13 is a cross sectional partial view showing the structure of the laser bar 210 taken along like F13-F13 in FIG. 12.

As shown in FIGS. 11 to 13, the method for manufacturing the semiconductor laser element 10 includes a step of forming separation grooves 220. In an example, this process is performed, for example, before the semiconductor wafer 200 is divided into the laser bars 210. When a plate-shaped substrate including the laser bars 210 is cut out from the semiconductor wafer 200, the step of forming the separation grooves 220 may be performed before the plate-shaped substrate is cut out. That is, the separation groove 220 is formed in the semiconductor wafer 200.

As shown in FIGS. 11 and 12, multiple separation grooves 220 are separate from each other and are arranged in the longitudinal direction of the laser bar 210. Each separation groove 220 extends in the transverse direction of the laser bar 210. The separation groove 220 is partially arranged in the transverse direction of the laser bar 210. That is, the separation groove 220 is separated from the two side surfaces 211 of the laser bars 210. The portions of the laser bar 210 between the separation groove 220 and the side surfaces 211 in the transverse direction define the first region 27 and the second region 28 (refer to FIG. 2).

Although not shown, each separation groove 220 extends from the semiconductor layer 40 (semiconductor layer laminated structure) to the semiconductor wafer 200. The separation groove 220 extends through the semiconductor layer 40 (semiconductor layer laminated structure) in the Z-direction. The separation groove 220 extends from the wafer front surface 201 through a portion of the semiconductor wafer 200 in the Z-direction. The separation groove 220 is formed by etching. In an example, the separation groove 220 is formed by dry etching.

As shown in FIG. 13, the separation groove 220 defines the first recess 60 and the second recess 70. The separation groove 220 has a tapered end, the width of which decreases toward the distal end. The separation groove 220 includes a first separation side surface 221 defining the first inner side surface 61, a second separation side surface 222 defining the second inner side surface 71, a first taper surface 223 defining an inclined surface 62A of the first connection surface 62, and a second taper surface 224 defining an inclined surface of the second connection surface 72. In the first embodiment, the first taper surface 223 and the second taper surface 224 are connected to form the tapered separation groove 220. The first taper surface 223 and the second taper surface 224 have a (111) plane.

The method for manufacturing the semiconductor laser element 10 includes a step of dividing the laser bar 210 into multiple semiconductor laser elements 10.

The laser bar 210 is cleaved along the separation grooves 220. In an example, when a blade (not shown) comes into contact with the laser bar 210 from the side of the back surface along each separation groove 220, the laser bar 210 receives an external stress. This causes the laser bar 210 to crack from the distal end of the separation groove 220, thereby dividing the laser bar 210 along the separation grooves 220. The steps described above manufacture the semiconductor laser element 10.

### Operation

The advantages of the semiconductor laser element 10 of the first embodiment will now be described.

When the laser bar 210 is cleaved to form multiple semiconductor laser elements 10, the laser bar 210 cracks in the thickness direction from the distal end of the separation groove 220 where the first taper surface 223 and the second taper surface 224 are connected. Thus, the laser bar 210 is readily cleaved.

For example, when a diamond cutter is used to form separation grooves to divide the laser bar 210 into multiple semiconductor laser elements 10, the width and depth may vary among the separation grooves. Then, when the laser bar 210 is cleaved, the laser bar 210 cracks from multiple points of the separation groove. This forms irregularities in the first side surface 25 of the semiconductor laser element 10.

In addition, a mechanical contact of the diamond cutter with the semiconductor wafer 200 may cause a portion of the semiconductor wafer 200 to be chipped and scattered as chip debris from where the separation groove is formed. Such chip debris may collect as contaminants on the first end surface 23 and the second end surface 24 of the semiconductor laser element 10, after being divided.

When laser cutting is used, instead of using a diamond cutter, to form a separation groove to divide the laser bar 210 into multiple semiconductor laser elements 10, the separation groove and its surrounding are melted by heat. Also, when laser cutting is used, the width and depth may vary among the separation grooves. Then, when the laser bar 210 is cleaved, the laser bar 210 cracks from multiple points of the separation groove. This forms irregularities in the first side surface 25 of the semiconductor laser element 10.

In the first embodiment, dry etching is used to form the separation groove 220 to divide the laser bar 210 into multiple semiconductor laser elements 10. In dry etching, the first separation side surface 221 and the second separation side surface 222 of the separation groove 220 are formed along the plane orientation of the laser bar 210. In other words, each of the first separation side surface 221 and the second separation side surface 222 has a (110) plane. Each of the first taper surface 223 and the second taper surface 224 has a (111) plane. This limits variations in depth of the separation groove 220. Accordingly, when the laser bar 210 is cleaved, irregularities are less likely to be formed in the first side surface 25 of the semiconductor laser element 10. In addition, since the separation groove 220 is formed without a mechanical contact of a diamond cutter, the semiconductor wafer 200 is less likely to be chipped. Thus, production of chip debris from the semiconductor wafer 200 is limited. Accordingly, collection of chip debris (contaminants) on the first end surface 23 and the second end surface 24 of the semiconductor laser element 10 is limited.

### Advantages

The semiconductor laser element 10 of the first embodiment has the advantages described below.

(1-1) The semiconductor laser element 10 includes the element front surface 21 and the element back surface 22 that face away from each other, the first end surface 23 and the second end surface 24 that face away from each other in the X-direction in plan view, the first side surface 25 and the second side surface 26 that face away from each other in the Y-direction, the element body 20 configured to emit laser light from the first end surface 23, the front electrode 51 formed on the element front surface 21, and the back electrode 52 formed on the element back surface 22. The element body 20 includes the first recess 60 recessed into the element body 20 between the first side surface 25 and the element front surface 21, and the second recess 70 recessed into the element body 20 between the second side surface 26 and the element front surface 21. The first recess 60 includes the first inner side surface 61 facing in the same direction as the first side surface 25, and the first connection surface 62 connecting the first inner side surface 61 and the first side surface 25. The second recess 70 includes the second inner side surface 71 facing in the same direction as the second side surface 26, and the second connection surface 72 connecting the second inner side surface 71 and the second side surface 26. The first connection surface 62 and the second connection surface 72 each include an inclined surface inclined relative to the element front surface 21 at an angle differing from those of the first side surface 25 and the second side surface 26.

With this structure, when the laser bar 210 is cleaved to form the semiconductor laser elements 10, formation of irregularities in the first side surface 25 and the second side surface 26 is limited by the inclined surfaces, namely, the first connection surface 62 and the second connection surface 72. This improves the quality of the first side surface 25 and the second side surface 26 as the cleaved surfaces.

(1-2) The angle θ1 of the first connection surface 62 relative to the element front surface 21 and the angle of the second connection surface 72 relative to the element front surface 21 are each greater than or equal to 50° and less than or equal to 60°.

With this structure, when the laser bar 210 is cleaved to form the semiconductor laser elements 10, formation of irregularities in the first side surface 25 and the second side surface 26 is further limited. This improves the quality of the first side surface 25 and the second side surface 26 as the cleaved surfaces.

(1-3) Each of the first recess 60 and the second recess 70 is partially arranged in the element body 20 in the X-direction.

With this structure, the laser bar 210 is less likely to crack during the handling of the laser bar 210 as compared with a structure in which the first recess 60 and the second recess 70 are entirely arranged in the element body 20 in the X-direction. This improves the ease of handling the laser bar 210.

(1-4) The element body 20 includes the first regions 27 located at opposite ends in the X-direction between the first side surface 25 and the element front surface 21 so that the first recess 60 is not formed in the first regions 27, and the second regions 28 located at opposite ends in the X-direction between the second side surface 26 and the element front surface 21 so that the second recess 70 is not formed in the second regions 28. A single first recess 60 is arranged between the first regions 27, which are located at opposite ends in the X-direction between the first side surface 25 and the element front surface 21. A single second recess 70 is arranged between the second regions 28, which are located at opposite ends in the X-direction between the second side surface 26 and the element front surface 21.

With this structure, the laser bar 210 is less likely to crack during the handling of the laser bar 210 as compared with a structure in which the first recess 60 is arranged in an end in the X-direction between the first side surface 25 and the element front surface 21, and the second recess 70 is arranged in an end in the X-direction between the second side surface 26 and the element front surface 21. This improves the ease of handling the laser bar 210.

(1-5) The length LX1 of the first recess 60 in the X-direction is greater than the length RX1 of each first region 27 in the X-direction. The length LX2 of the second recess 70 in the X-direction is greater than the length RX2 of each second region 28 in the X-direction.

With this structure, the laser bar 210 cleaves more easily than with a structure in which the length LX1 of the first recess 60 in the X-direction is less than the length RX1 of each first region 27 in the X-direction, and the length LX2 of the second recess 70 in the X-direction is less than the length RX2 of each second region 28 in the X-direction.

(1-6) The ratio (LX1/LS) of the length LX1 of the first recess 60 in the X-direction to the length LS of the element body 20 in the X-direction and the ratio (LX2/LS) of the length LX2 of the second recess 70 in the X-direction to the length LS of the element body 20 in the X-direction are each greater than or equal to ⅝ and less than or equal to ⅞.

With this structure, the laser bar 210 is less likely to crack during the handling of the laser bar 210. Thus, the ease of handling the laser bar 210 is improved while the laser bar 210 readily cleaves.

(1-7) The first recess 60 includes the first end connection surfaces 63A and 63B arranged on opposite ends in the X-direction. The second recess 70 includes the second end connection surfaces 73A and 73B arranged on opposite ends in the X-direction. The angle θ2 of each of the first end connection surfaces 63A and 63B relative to the first inner side surface 61 and the angle of each of the second end connection surfaces 73A and 73B relative to the second inner side surface 71 are greater than the angle θA of the first connection surface 62 relative to the first inner side surface 61 and the angle of the second connection surface 72 relative to the second inner side surface 71, respectively.

With this structure, the laser bar 210 is less likely to crack during the handling of the laser bar 210 as compared with a structure in which the angle θ2 of each of the first end connection surfaces 63A and 63B relative to the first inner side surface 61 and the angle of each of the second end connection surfaces 73A and 73B relative to the second inner side surface 71 are less than or equal to the angle θA of the first connection surface 62 relative to the first inner side surface 61 and the angle of the second connection surface 72 relative to the second inner side surface 71, respectively. This improves the ease of handling the laser bar 210.

(1-8) The angle θ2 of the first end connection surfaces 63A and 63B relative to the first inner side surface 61 and the angle of the second end connection surfaces 73A and 73B relative to the second inner side surface 71 are greater than or equal to 85° and less than or equal to 95°.

With this structure, the laser bar 210 is less likely to crack during the handling of the laser bar 210 as compared with a structure in which the angle θ2 of the first end connection surfaces 63A and 63B relative to the first inner side surface 61 and the angle of the second end connection surfaces 73A and 73B relative to the second inner side surface 71 are less than 85° or greater than 95°. This improves the ease of handling the laser bar 210.

(1-9) The angle θ2 of the first end connection surfaces 63A and 63B relative to the first inner side surface 61 and the angle of the second end connection surfaces 73A and 73B relative to the second inner side surface 71 are greater than or equal to 87° and less than or equal to 93°.

With this structure, the laser bar 210 is less likely to crack during the handling of the laser bar 210 as compared with a structure in which the angle θ2 of the first end connection surfaces 63A and 63B relative to the first inner side surface 61 and the angle of the second end connection surfaces 73A and 73B relative to the second inner side surface 71 are less than 87° or greater than 93°. This improves the ease of handling the laser bar 210.

(1-10) The angle θ2 of the first end connection surfaces 63A and 63B relative to the first inner side surface 61 and the angle of the second end connection surfaces 73A and 73B relative to the second inner side surface 71 are greater than or equal to 88° and less than or equal to 92°.

With this structure, the laser bar 210 is less likely to crack during the handling of the laser bar 210 as compared with a structure in which the angle θ2 of the first end connection surfaces 63A and 63B relative to the first inner side surface 61 and the angle of the second end connection surfaces 73A and 73B relative to the second inner side surface 71 are less than 88° or greater than 92°. This improves the ease of handling the laser bar 210.

(1-11) The first recess 60 includes the first end connection surfaces 63A and 63B arranged on opposite ends in the X-direction. The second recess 70 includes the second end connection surfaces 73A and 73B arranged on opposite ends in the X-direction. The length LE of each of the first end connection surfaces 63A and 63B between the first inner side surface 61 and the first side surface 25 and the length of each of the second end connection surfaces 73A and 73B between the second inner side surface 71 and the second side surface 26 are less than the length LC of the first connection surface 62 in the inclination direction and the length of the second connection surface 72 in the inclination direction, respectively.

With this structure, the laser bar 210 is less likely to crack during the handling of the laser bar 210 as compared with a structure in which the length LE of each of the first end connection surfaces 63A and 63B between the first inner side surface 61 and the first side surface 25 and the length of each of the second end connection surfaces 73A and 73B between the second inner side surface 71 and the second side surface 26 are greater than the length LC of the first connection surface 62 in the inclination direction and the length of the second connection surface 72 in the inclination direction, respectively. This improves the ease of handling the laser bar 210.

(1-12) The separation groove 220, which includes the first recess 60 and the second recess 70, is formed by removing the semiconductor layer 40 and the semiconductor substrate 30 from the element body 20 through dry etching.

With this configuration, the separation groove 220 is less likely to vary in width and depth than with a configuration that uses a diamond cutter or laser cutting to form the first recess 60 and the second recess 70. Accordingly, when the laser bar 210 is cleaved, irregularities are less likely to be formed in the first side surface 25 of the semiconductor laser element 10.

### Second Embodiment

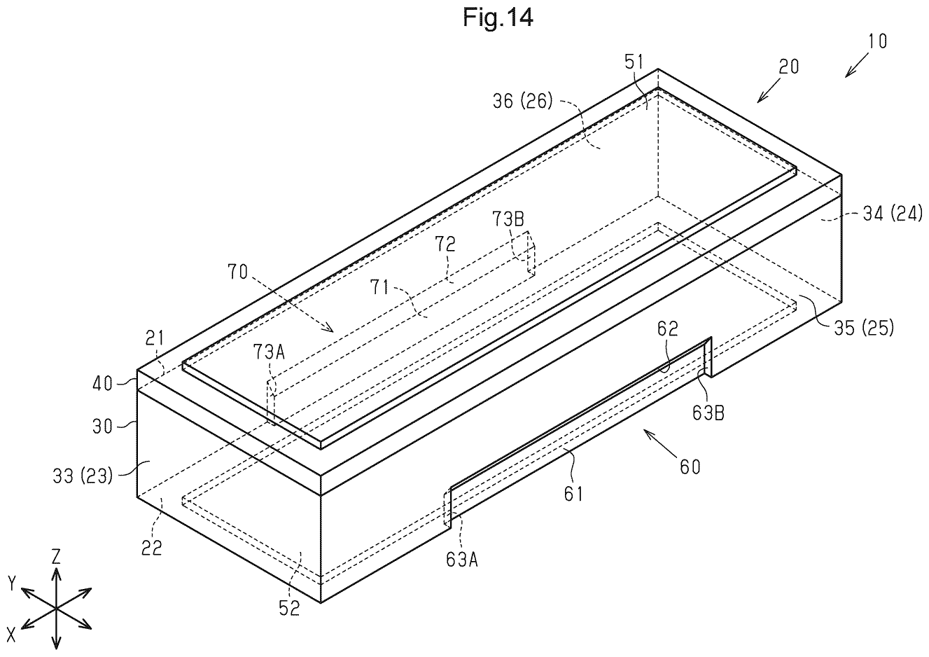

A second embodiment of a semiconductor laser element 10 will now be described with reference to FIGS. 14 to 16. The second embodiment of the semiconductor laser element 10 differs from the first embodiment of the semiconductor laser element 10 mainly in positions where the first recess 60 and the second recess 70 are formed. In the description hereafter, same reference characters are given to those components that are the same as the corresponding components of the semiconductor laser element 10 in the first embodiment. Such components will not be described in detail.

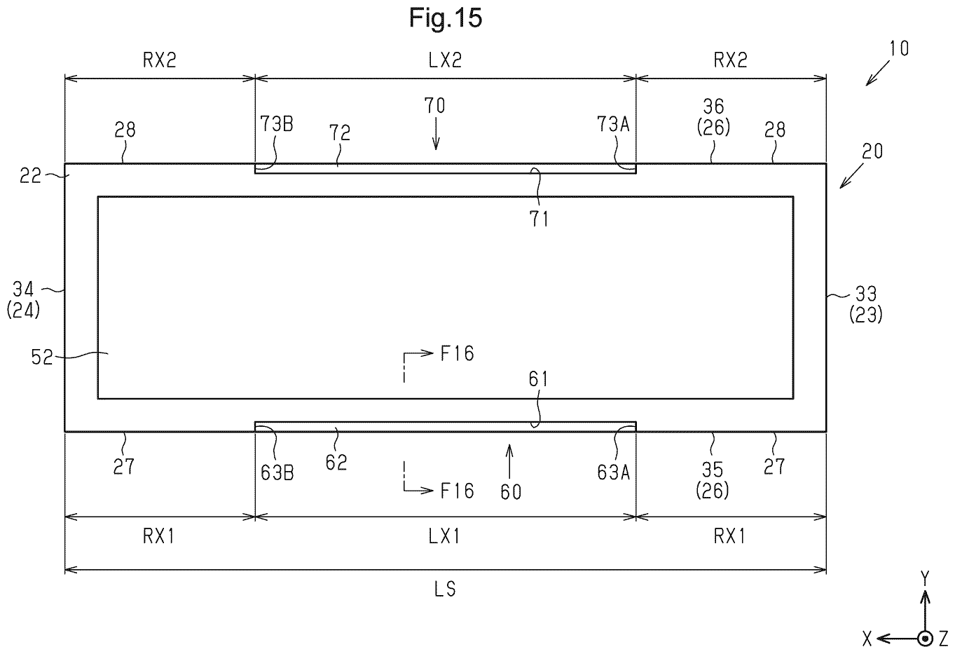

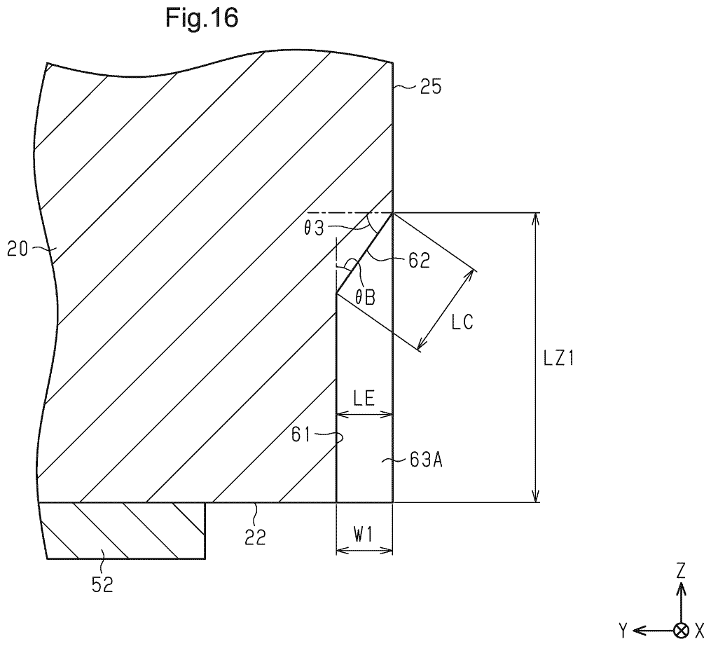

FIG. 14 is a schematic perspective view showing the structure of the semiconductor laser element 10 in the second embodiment. FIG. 15 is a schematic plan view showing the structure of the semiconductor laser element 10 shown in FIG. 14 viewed from the side of the element back surface 22. FIG. 16 is a cross-sectional view of the semiconductor laser element 10 taken along line F16-F16 in FIG. 15 enlarging the first recess 60 and its surroundings.

As shown in FIG. 14, the first recess 60 is arranged between the first side surface 25 and the element back surface 22 of the element body 20. The second recess 70 is arranged between the second side surface 26 and the element back surface 22 of the element body 20. The first recess 60 and the second recess 70 are recessed into the element body 20. The first recess 60 and the second recess 70 are arranged in the semiconductor substrate 30. The first recess 60 and the second recess 70 are not arranged in the semiconductor layer 40, which differs from the first embodiment.

As shown in FIG. 15, the first recess 60 includes the first inner side surface 61 facing in the same direction as the first side surface 25 and the first connection surface 62 connecting the first inner side surface 61 and the first side surface 25.

The first inner side surface 61 is connected to the element back surface 22. The first inner side surface 61 is formed in a portion of the element body 20 located toward the element back surface 22 in the Z-direction. More specifically, the first inner side surface 61 is formed in a portion of the semiconductor substrate 30 located toward the substrate back surface 32 in the Z-direction. In an example, the first inner side surface 61 is parallel to the first side surface 25.

As shown in FIG. 14, the first connection surface 62 is arranged closer to the element front surface 21 than the first inner side surface 61 is. The first connection surface 62 includes an inclined surface inclined relative to the element back surface 22 at an angle differing from those of the first side surface 25 and the second side surface 26. More specifically, the first connection surface 62 is inclined toward the first side surface 25 as the first connection surface 62 extends from the first inner side surface 61 toward the element front surface 21 in the Z-direction. As shown in FIG. 16, the first connection surface 62 has an angle θ3 that is greater than or equal to 50° and less than or equal to 60° relative to the element back surface 22. Preferably, the angle θ3 is greater than or equal to 53° and less than or equal to 57°. The length LC of the first connection surface 62 in the inclination direction is less than the length of the first inner side surface 61 in the Z-direction. The length LC is, for example, equal to the length LC described in the first embodiment.

In a direction (in the second embodiment, the Y-direction) orthogonal to the first side surface 25, the distance W1 between the first side surface 25 and the first inner side surface 61 is equal to the distance W1 (refer to FIG. 4) described in the first embodiment. In the example shown in FIG. 16, the distance W1 is greater than or equal to 1 μm and less than or equal to 5 μm.

As shown in FIG. 15, the first recess 60 includes first end connection surfaces 63A and 63B arranged on opposite ends in the X-direction. The first end connection surfaces 63A and 63B are connected to the element back surface 22. The first end connection surfaces 63A and 63B of the second embodiment are identical in shape and size to those of the first embodiment. Thus, the angle of the first end connection surface 63A relative to the first inner side surface 61 is equal to the angle θ2 shown in FIG. 7. Therefore, the angle of the first end connection surface 63A relative to the first inner side surface 61 is greater than an angle θB of the first connection surface 62 relative to the first inner side surface 61. In an example, the angle of the first end connection surface 63A relative to the first inner side surface 61 is greater than or equal to 85° and less than or equal to 95°. In an example, the angle of the first end connection surface 63A relative to the first inner side surface 61 is greater than or equal to 87° and less than or equal to 93°. In an example, the angle of the first end connection surface 63A relative to the first inner side surface 61 is greater than or equal to 88° and less than or equal to 92°. In an example, the angle of the first end connection surface 63A relative to the first inner side surface 61 is greater than or equal to 89° and less than or equal to 91°. The first end connection surface 63B has the same structure as the first end connection surface 63A.

The second recess 70 includes the second inner side surface 71 facing in the same direction as the second side surface 26, and the second connection surface 72 connecting the second inner side surface 71 and the second side surface 26. The second inner side surface 71 is connected to the element back surface 22. The second connection surface 72 includes an inclined surface inclined relative to the element back surface 22 at an angle differing from those of the first side surface 25 and the second side surface 26. The second recess 70 includes the second end connection surfaces 73A and 73B arranged on opposite ends in the X-direction. The second end connection surfaces 73A and 73B are connected to the element back surface 22.

The second recess 70 and the first recess 60 are identical in shape and size. The angle of the second connection surface 72 relative to the element back surface 22 is equal to the angle θ3 of the first connection surface 62 relative to the element back surface 22. The angle of the second connection surface 72 relative to the element back surface 22 is greater than or equal to 50° and less than or equal to 60°. Preferably, the angle of the second connection surface 72 relative to the element back surface 22 is greater than or equal to 53° and less than or equal to 57°. In a direction (in the second embodiment, the Y-direction) orthogonal to the second side surface 26, the distance between the second side surface 26 and the second inner side surface 71 is equal to the distance W1. More specifically, in the direction orthogonal to the second side surface 26, the distance between the second side surface 26 and the second inner side surface 71 is greater than or equal to 1 μm and less than or equal to 5 μm. The angle of each of the second end connection surfaces 73A and 73B relative to the second inner side surface 71 is equal to the angle of the first end connection surface 63A relative to the first inner side surface 61. Thus, the angle of each of the second end connection surfaces 73A and 73B relative to the second inner side surface 71 is greater than the angle of the second connection surface 72 relative to the second inner side surface 71. The angle of each of the second end connection surfaces 73A and 73B relative to the second inner side surface 71 may be, for example, greater than or equal to 85° and less than or equal to 95°, greater than or equal to 87° and less than or equal to 93°, greater than or equal to 88° and less than or equal to 92°, or greater than or equal to 89° and less than or equal to 91°. The length of each of the second end connection surfaces 73A and 73B between the second inner side surface 71 and the second side surface 26 is equal to the length of the first end connection surface 63A between the first inner side surface 61 and the first side surface 25. Therefore, the length of each of the second end connection surfaces 73A and 73B between the second inner side surface 71 and the second side surface 26 is less than the length of the second connection surface 72 in the inclination direction. The length of each of the second end connection surfaces 73A and 73B between the second inner side surface 71 and the second side surface 26 may be, for example, greater than or equal to 1 μm and less than or equal to 5 μm.

### Advantages

The semiconductor laser element 10 of the second embodiment has the advantages described below.

(2-1) The semiconductor laser element 10 includes the element front surface 21 and the element back surface 22 that face away from each other, the first end surface 23 and the second end surface 24 that face away from each other in the X-direction in plan view, the first side surface 25 and the second side surface 26 that face away from each other in the Y-direction, the element body 20 configured to emit laser light from the first end surface 23, the front electrode 51 formed on the element front surface 21, and the back electrode 52 formed on the element back surface 22. The element body 20 includes the first recess 60 recessed into the element body 20 between the first side surface 25 and the element back surface 22, and the second recess 70 recessed into the element body 20 between the second side surface 26 and the element back surface 22. The first recess 60 includes a first inner side surface 61 facing in the same direction as the first side surface 25 and a first connection surface 62 connecting the first inner side surface 61 and the first side surface 25. The second recess 70 includes the second inner side surface 71 facing in the same direction as the second side surface 26, and the second connection surface 72 connecting the second inner side surface 71 and the second side surface 26. The first connection surface 62 and the second connection surface 72 each include an inclined surface inclined relative to the element back surface 22 at an angle differing from those of the first side surface 25 and the second side surface 26.

With this structure, when the laser bar 210 is cleaved to form the semiconductor laser elements 10, formation of irregularities in the first side surface 25 and the second side surface 26 is limited by the inclined surfaces, namely, the first connection surface 62 and the second connection surface 72. This improves the quality of the first side surface 25 and the second side surface 26 as the cleaved surfaces. The semiconductor laser element 10 of the second embodiment has advantages similar to the advantages (1-2) to (1-12) in the first embodiment.

### Modified Examples

The embodiments described above may be modified, for example, as follows. The embodiments and the modified examples described below may be combined as long as there is no technical contradiction. In the modified examples described hereafter, same reference characters are given to those components that are the same as the corresponding components of the above embodiments. Such components will not be described in detail.

In the first embodiment, the angle θ1 of the first connection surface 62 of the first recess 60 relative to the element front surface 21 and the angle of the second connection surface 72 of the second recess 70 relative to the element front surface 21 may be changed in any manner. In an example, the angle θ1 of the first connection surface 62 relative to the element front surface 21 and the angle of the second connection surface 72 relative to the element front surface 21 may be greater than 45° and less than 55°.

In the second embodiment, the angle θ3 of the first connection surface 62 of the first recess 60 relative to the element back surface 22 and the angle of the second connection surface 72 of the second recess 70 relative to the element back surface 22 may be changed in any manner. In an example, the angle θ3 of the first connection surface 62 relative to the element back surface 22 and the angle of the second connection surface 72 relative to the element back surface 22 may be greater than 45° and less than 55°.

In each embodiment, the distance W1 between the first side surface 25 and the first inner side surface 61 in a direction orthogonal to the first inner side surface 61 of the first recess 60 and the distance between the second side surface 26 and the second inner side surface 71 in a direction orthogonal to the second inner side surface 71 of the second recess 70 may be changed in any manner.

In each embodiment, the length LC of the first connection surface 62 in the inclination direction and the length of the second connection surface 72 in the inclination direction may be changed in any manner. In an example, the length LC of the first connection surface 62 in the inclination direction and the length of the second connection surface 72 in the inclination direction may be less than 2 μm or may be greater than 8 μm.

In each embodiment, the first recess 60 and the second recess 70 may extend through the entirety of the element body 20 in the X-direction (first direction).

In each embodiment, the length LX1 of the first recess 60 in the X-direction (first direction) and the length LX2 of the second recess 70 in the X-direction (first direction) may be changed in any manner. In an example, the length LX1 of the first recess 60 in the X-direction may be less than or equal to the length RX1 of the first region 27 of the element body 20 in the X-direction (first direction). In an example, the length LX1 of the first recess 60 in the X-direction may be less than or equal to the length RX2 of the second region 28 of the element body 20 in the X-direction (first direction). In an example, the length LX2 of the second recess 70 in the X-direction may be less than or equal to the length RX1 of the first region 27 of the element body 20 in the X-direction. In an example, the length LX2 of the second recess 70 in the X-direction may be less than or equal to the length RX2 of the second region 28 of the element body 20 in the X-direction.

The ratio (LX1/LS) of the length LX1 of the first recess 60 in the X-direction (first direction) to the length LS of the element body 20 in the X-direction and the ratio (LX2/LS) of the length LX2 of the second recess 70 in the X-direction to the length LS of the element body 20 in the X-direction may be less than ⅝ or greater than ⅞.

In each embodiment, the first recess 60 may be arranged so as to be connected to the first end surface 23 or the second end surface 24 of the element body 20.

In each embodiment, the second recess 70 may be arranged so as to be connected to the first end surface 23 or the second end surface 24 of the element body 20.

In each embodiment, multiple first recesses 60 may be separate from each other and arranged in the X-direction (first direction).

In each embodiment, multiple second recesses 70 may be separate from each other and arranged in the X-direction (first direction).

In each embodiment, the angle θ2 of each of the first end connection surfaces 63A and 63B of the first recess 60 relative to the first side surface 25 may be less than 85°. In this case, the angle θ2 of each of the first end connection surfaces 63A and 63B of the first recess 60 relative to the first side surface 25 may be, for example, less than or equal to the angle θA of the first connection surface 62 relative to the first inner side surface 61.

In each embodiment, the angle of each of the second end connection surfaces 73A and 73B of the second recess 70 relative to the second side surface 26 may be less than 85°. In this case, the angle of each of the second end connection surfaces 73A and 73B of the second recess 70 relative to the second side surface 26 may be less than or equal to, for example, the angle of the second connection surface 72 relative to the second inner side surface 71.

In each embodiment, the length LE of each of the first end connection surfaces 63A and 63B between the first inner side surface 61 and the first side surface 25 may be changed in any manner. In an example, the length LE of each of the first end connection surfaces 63A and 63B between the first inner side surface 61 and the first side surface 25 may be less than 1 μm or greater than 5 μm.

In each embodiment, the length of each of the second end connection surfaces 73A and 73B between the second inner side surface 71 and the second side surface 26 may be changed in any manner. In an example, the length of each of the second end connection surfaces 73A and 73B between the second inner side surface 71 and the second side surface 26 may be less than 1 μm or greater than 5 μm.

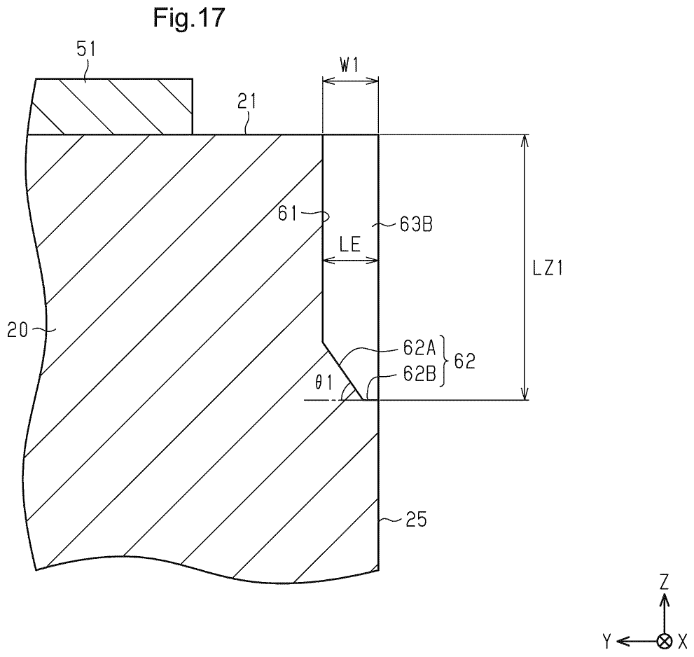

In each embodiment, the structure of the first connection surface 62 of the first recess 60 may be changed in any manner. In an example, as shown in FIG. 17, the first connection surface 62 includes the inclined surface 62A and a flat surface 62B. The inclined surface 62A is connected to the first inner side surface 61. The inclined surface 62A shown in FIG. 17 has the same structure as the first connection surface 62 of the first embodiment. In other words, the first connection surface 62 includes the inclined surface 62A inclined relative to the element front surface 21 at an angle differing from those of the first side surface 25 and the second side surface 26. The flat surface 62B connects the inclined surface 62A and the first side surface 25. The flat surface 62B faces, for example, the same direction as the element front surface 21. The second connection surface 72 of the second recess 70 may include an inclined surface and a flat surface in the same manner as the first connection surface 62.

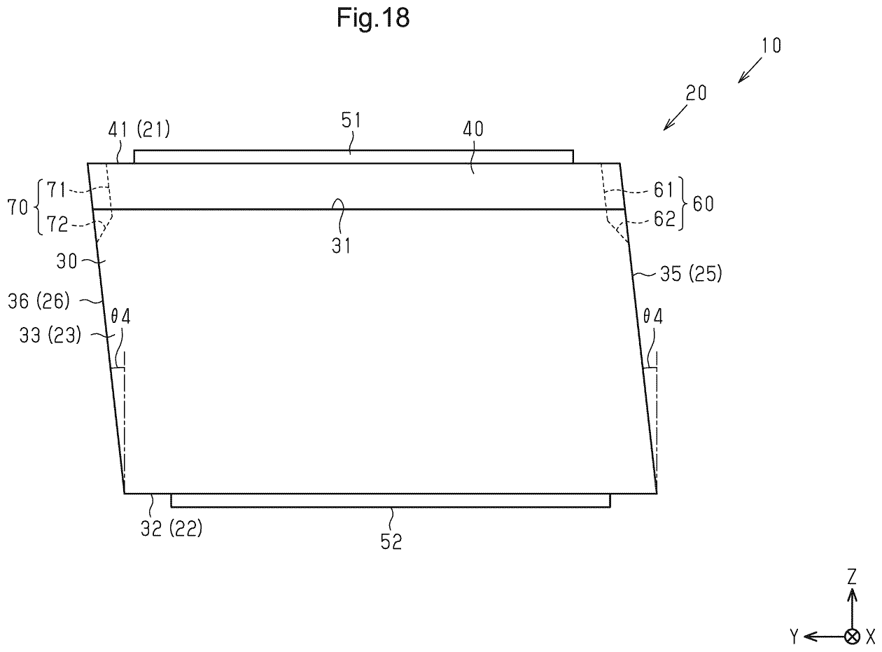

In each embodiment, the semiconductor substrate 30 may have an off-angle. In an example, the semiconductor substrate 30 may have an off-angle of 10°. More specifically, as shown in FIG. 18, the first substrate side surface 35 and the second substrate side surface 36 of the semiconductor substrate 30 are inclined relative to a direction (the Z-direction) orthogonal to the substrate front surface 31. An angle θ4 of each of the first substrate side surface 35 and the second substrate side surface 36 relative to a direction orthogonal to the substrate front surface 31 is 10°. Taking into consideration manufacturing errors of the semiconductor substrate 30, the angle θ4 of each of the first substrate side surface 35 and the second substrate side surface 36 relative to the direction orthogonal to the substrate front surface 31 being 10° includes angles of the first substrate side surface 35 and the second substrate side surface 36 relative to the direction orthogonal to the substrate front surface 31 being greater than or equal to 8° and less than or equal to 12°.

In the example shown in FIG. 18, the first inner side surface 61 of the first recess 60 and the second inner side surface 71 of the second recess 70 are inclined relative to a direction (the Z-direction) orthogonal to the substrate front surface 31. The first inner side surface 61 and the second inner side surface 71 each have an angle relative to a direction orthogonal to the substrate front surface 31 that is equal to the angle θ4. In other words, the first inner side surface 61 is parallel to the first side surface 25, and the second inner side surface 71 is parallel to the second side surface 26. In this case, the angle of the first connection surface 62 relative to the element front surface 21 and the angle of the second connection surface 72 relative to the element front surface 21 are each greater than or equal to 30° and less than or equal to 40°.

The inclined surface 62A of the first connection surface 62 in the second embodiment has the same structure of the first connection surface 62 described in the second embodiment. In other words, the first connection surface 62 includes an inclined surface inclined relative to the element back surface 22 at an angle differing from those of the first side surface 25 and the second side surface 26. The flat surface faces, for example, the same direction as the element back surface 22. In the second embodiment, the second connection surface 72 of the second recess 70 may include an inclined surface and a flat surface in the same manner as the first connection surface 62.

In each embodiment, the p-type semiconductor layer 46 of the semiconductor layer 40 may be changed in any manner. In an example, the p-type semiconductor layer 46 may include a single p-type cladding layer. In this case, the p-type semiconductor layer 46 includes a single p-type etching stopper layer.

One or more of the various examples described in this specification may be combined as long as there is no technical contradiction.

Terms such as “first,” “second,” and “third” in this disclosure are used to distinguish subjects and not used for ordinal purposes.

In this specification, “at least one of A and B” should be understood to mean “only A, or only B, or both A and B.”

In the present disclosure, the term “on” includes the meaning of “above” in addition to the meaning of “on” unless otherwise clearly described in the context. Accordingly, for example, the expression of “first element arranged on second element” may mean that the first element is arranged directly on the second element in one embodiment and mean that the first element is arranged above the second element without contacting the second element in another embodiment. In other words, the term “on” will also allow for a structure in which another element is formed between the first element and the second element.

The Z-direction as referred to in the present disclosure does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### CLAUSES

The technical aspects that are understood from the present disclosure will hereafter be described. Reference characters used in the described embodiment are added to corresponding elements in the clauses to aid understanding without any intention to impose limitations on these elements. The reference characters are used as examples to facilitate understanding, and the elements in each clause are not limited to those elements given with the reference characters.

### [Clause A1]

A semiconductor laser element (10), including:
an element body (20) including an element front surface (21) and an element back surface (22) that face away from each other, the element front surface (21) facing in a thickness direction (Z-direction), a first end surface (23) and a second end surface (24) that face away from each other in a first direction (X-direction) as viewed in the thickness direction (Z-direction), and a first side surface (25) and a second side surface (26) that face away from each other in a second direction (Y-direction) orthogonal to the first direction (X-direction) as viewed in the thickness direction (Z-direction), the element body (20) being configured to emit laser light from the first end surface (23);
a front electrode (51) formed on the element front surface (21); and
a back electrode (52) formed on the element back surface (22), where
the element body (20) includes
   a first recess (60) recessed into the element body (20) between the first side surface (25) and the element front surface (21), and
   a second recess (70) recessed into the element body (20) between the second side surface (26) and the element front surface (21),
the first recess (60) includes a first inner side surface (61) facing in the same direction as the first side surface (25) and a first connection surface (62) connecting the first inner side surface (61) and the first side surface (25),
the second recess (70) includes a second inner side surface (71) facing in the same direction as the second side surface (26) and a second connection surface (72) connecting the second inner side surface (71) and the second side surface (26), and
the first connection surface (62) and the second connection surface (72) each include an inclined surface inclined relative to the element front surface (21) at an angle differing from those of the first side surface (25) and the second side surface (26).

### [Clause A2]

The semiconductor laser element according to clause A1, where an angle (θ1) of the inclined surface of the first connection surface (62) relative to the element front surface (21) and an angle of the inclined surface of the second connection surface (72) relative to the element front surface (21) are each greater than or equal to 50° and less than or equal to 60°.

### [Clause A3]

The semiconductor laser element according to clause A1 or A2, where a distance (W1) between the first side surface (25) and the first inner side surface (61) in a direction (Y-direction) orthogonal to the first inner side surface (61) and a distance between the second side surface (26) and the second inner side surface (71) in a direction (Y-direction) orthogonal to the second inner side surface (71) are each greater than or equal to 1 μm and less than or equal to 5 μm.

### [Clause A4]

The semiconductor laser element according to any one of clauses A1 to A3, where a length (LC) of the inclined surface of the first connection surface (62) in an inclination direction and a length of the inclined surface of the second connection surface (72) in an inclination direction are each greater than or equal to 2 μm and less than or equal to 8 μm.

### [Clause A5]

The semiconductor laser element according to any one of clauses A1 to A4, where each of the first recess (60) and the second recess (70) is partially arranged in the element body (20) in the first direction (X-direction).

### [Clause A6]

The semiconductor laser element according to clause A5, where
the element body (20) includes
   first regions (27) located at opposite ends of the element body (20) in the first direction (X-direction) between the first side surface (25) and the element front surface (21) so that the first recess (60) is not formed in the first regions (27), and
   second regions (28) located at opposite ends of the element body (20) in the first direction (X-direction) between the second side surface (26) and the element front surface (21) so that the second recess (70) is not formed in the second regions (28),
the first recess (60) is a single first recess (60) arranged between the first regions (27), which are located at opposite ends in the first direction (X-direction) between the first side surface (25) and the element front surface (21), and
the second recess (70) is a single second recess (70) arranged between the second regions (28), which are located at opposite ends in the first direction (X-direction) between the second side surface (26) and the element front surface (21).

### [Clause A7]

The semiconductor laser element according to clause A6, where
a length (LX1) of the first recess (60) in the first direction (X-direction) is greater than a length (RX1) of each first region (27) in the first direction (X-direction), and
a length (LX2) of the second recess (70) in the first direction (X-direction) is greater than a length (RX2) of each second region (28) in the first direction (X-direction).

### [Clause A8]

The semiconductor laser element according to clause A6, where
a ratio (LX1/LS) of a length (LX1) of the first recess (60) in the first direction (X-direction) to a length (LS) of the element body (20) in the first direction (X-direction) is greater than or equal to ⅝ and less than or equal to ⅞, and
a ratio (LX2/LS) of a length (LX2) of the second recess (70) in the first direction (X-direction) to a length (LS) of the element body (20) in the first direction (X-direction) is greater than or equal to ⅝ and less than or equal to ⅞.

### [Clause A9]

The semiconductor laser element according to any one of clauses A6 to A8, where
the first recess (60) includes first end connection surfaces (63A, 63B) arranged on opposite ends of the first recess (60) in the first direction (X-direction),
the second recess (70) includes second end connection surfaces (73A, 73B) arranged on opposite ends of the second recess (70) in the first direction (X-direction), and
an angle (θ2) of each of the first end connection surfaces (63A, 63B) relative to the first inner side surface (61) and an angle of each of the second end connection surfaces (73A, 73B) relative to the second inner side surface (71) are greater than an angle (θA) of the inclined surface of the first connection surface (62) relative to the first inner side surface (61) and an angle of the inclined surface of the second connection surface (72) relative to the second inner side surface (71), respectively.

### [Clause A10]

The semiconductor laser element according to clause A9, where
an angle (θ2) of each of the first end connection surfaces (63A, 63B) relative to the first inner side surface (61) is greater than or equal to 85° and less than or equal to 95°, and
an angle of each of the second end connection surfaces (73A, 73B) relative to the second inner side surface (71) is greater than or equal to 85° and less than or equal to 95°.

### [Clause A11]

The semiconductor laser element according to clause A9, where
an angle (θ2) of each of the first end connection surfaces (63A, 63B) relative to the first inner side surface (61) is greater than or equal to 87° and less than or equal to 93°, and
an angle of each of the second end connection surfaces (73A, 73B) relative to the second inner side surface (71) is greater than or equal to 87° and less than or equal to 93°.

### [Clause A12]

The semiconductor laser element according to clause A9, where
an angle (θ2) of each of the first end connection surfaces (63A, 63B) relative to the first inner side surface (61) is greater than or equal to 88° and less than or equal to 92°, and
an angle of each of the second end connection surfaces (73A, 73B) relative to the second inner side surface (71) is greater than or equal to 88° and less than or equal to 92°.

### [Clause A13]

The semiconductor laser element according to any one of clauses A6 to A8, where
the first recess (60) includes first end connection surfaces (63A, 63B) arranged on opposite ends of the first recess (60) in the first direction (X-direction),
the second recess (70) includes second end connection surfaces (73A, 73B) arranged on opposite ends of the second recess (70) in the first direction (X-direction), and
a length (LE) of each of the first end connection surfaces (63A, 63B) between the first inner side surface (61) and the first side surface (25) and a length of each of the second end connection surfaces (73A, 73B) between the second inner side surface (71) and the second side surface (26) are less than a length (LC) of the inclined surface of the first connection surface (62) in an inclination direction and a length of the inclined surface of the second connection surface (72) in an inclination direction, respectively.

### [Clause A14]

The semiconductor laser element according to clause A13, where
a length of each of the first end connection surfaces (63A, 63B) between the first inner side surface (61) and the first side surface (25) is greater than or equal to 1 μm and less than or equal to 5 μm, and
a length of each of the second end connection surfaces (73A, 73B) between the second inner side surface (71) and the second side surface (26) is greater than or equal to 1 μm and less than or equal to 5 μm.

### [Clause A15]

The semiconductor laser element according to any one of clauses A1 to A14, where
the element body (20) includes
   a semiconductor substrate (30) including a substrate back surface (32) including the element back surface (22) and a substrate front surface (31) facing away from the substrate back surface (32), and
   a semiconductor layer (40) arranged on the substrate front surface (31) and including a front surface (41) defining the element front surface (21) and an active layer (42) configured to emit the laser light, and
the first recess (60) and the second recess (70) extend from the semiconductor layer (40) to the semiconductor substrate (30).

### [Clause A16]

The semiconductor laser element according to clause A15, where the semiconductor layer (40) includes
an n-type cladding layer (45A) arranged closer to the semiconductor substrate (30) than the active layer (42) is, and
a p-type cladding layer (46A, 46C) arranged at a side of the active layer (42) opposite from the n-type cladding layer (45A).

### [Clause A17]

The semiconductor laser element according to clause A15 or A16, where the semiconductor substrate (30) is composed of a GaAs substrate.

### [Clause A18]

The semiconductor laser element according to any one of clauses A15 to A17, where
the semiconductor substrate (30) includes
   a first substrate end surface (33) and a second substrate end surface (34) facing away from each other in the first direction (X-direction), and
   a first substrate side surface (35) and a second substrate side surface (36) facing away from each other in the second direction (Y-direction),
an angle of the first substrate side surface (35) relative to the substrate front surface (31) is 90°, and
an angle of the second substrate side surface (36) relative to the substrate front surface (31) is 90°.

### [Clause A19]

The semiconductor laser element according to any one of clauses A15 to A17, where
the semiconductor substrate (30) includes
   a first substrate end surface (33) and a second substrate end surface (34) facing away from each other in the first direction (X-direction), and
   a first substrate side surface (35) and a second substrate side surface (36) facing away from each other in the second direction (Y-direction),
the first substrate side surface (35) and the second substrate side surface (36) are each inclined relative to a direction (Z-direction) orthogonal to the substrate front surface (31), and
the first substrate side surface (35) and the second substrate side surface (36) are each inclined 10° relative to a direction (Z-direction) orthogonal to the substrate front surface (31).

### [Clause B1]

A semiconductor laser element (10), including:
an element body (20) including an element front surface (21) and an element back surface (22) that face away from each other, the element front surface (21) facing in a thickness direction (Z-direction), a first end surface (23) and a second end surface (24) that face away from each other in a first direction (X-direction) as viewed in the thickness direction (Z-direction), and a first side surface (25) and a second side surface (26) that face away from each other in a second direction (Y-direction) orthogonal to the first direction (X-direction) as viewed in the thickness direction (Z-direction), the element body (20) being configured to emit laser light from the first end surface (23);
a front electrode (51) formed on the element front surface (21); and
a back electrode (52) formed on the element back surface (22), where
the element body (20) includes
   a first recess (60) recessed into the element body (20) between the first side surface (25) and the element back surface (22), and
   a second recess (70) recessed into the element body (20) between the second side surface (26) and the element back surface (22),
the first recess (60) includes a first inner side surface (61) facing in the same direction as the first side surface (25) and a first connection surface (62) connecting the first inner side surface (61) and the first side surface (25),
the second recess (70) includes a second inner side surface (71) facing in the same direction as the second side surface (26) and a second connection surface (72) connecting the second inner side surface (71) and the second side surface (26), and
the first connection surface (62) and the second connection surface (72) each include an inclined surface inclined relative to the element back surface (22) at an angle differing from those of the first side surface (25) and the second side surface (26).

### [Clause B2]

The semiconductor laser element according to clause B1, where an angle (θ3) of the inclined surface of the first connection surface (62) relative to the element back surface (22) and an angle of the inclined surface of the second connection surface (72) relative to the element back surface (22) are each greater than or equal to 50° and less than or equal to 60°.

### [Clause B3]

The semiconductor laser element according to clause B1 or B2, where a distance (W1) between the first side surface (25) and the first inner side surface (61) in a direction (Y-direction) orthogonal to the first inner side surface (61) and a distance between the second side surface (26) and the second inner side surface (71) in a direction (Y-direction) orthogonal to the second inner side surface (71) are each greater than or equal to 1 μm and less than or equal to 5 μm.

### [Clause B4]

The semiconductor laser element according to any one of clauses B1 to B3, where a length (LC) of the inclined surface of the first connection surface (62) in an inclination direction and a length of the inclined surface of the second connection surface (72) in an inclination direction are each greater than or equal to 2 μm and less than or equal to 8 μm.

### [Clause B5]

The semiconductor laser element according to any one of clauses B1 to B4, where each of the first recess (60) and the second recess (70) is partially arranged in the element body (20) in the first direction (X-direction).

### [Clause B6]

The semiconductor laser element according to clause B5, where
the element body (20) includes
   first regions (27) located at opposite ends of the element body (20) in the first direction (X-direction) between the first side surface (25) and the element back surface (22) so that the first recess (60) is not formed in the first regions (27), and
   second regions (28) located at opposite ends of the element body (20) in the first direction (X-direction) between the second side surface (26) and the element back surface (22) so that the second recess (70) is not formed in the second regions (28),
the first recess (60) is a single first recess (60) arranged between the first regions (27), which are located at opposite ends in the first direction (X-direction) between the first side surface (25) and the element back surface (22), and
the second recess (70) is a single second recess (70) arranged between the second regions (28), which are located at opposite ends in the first direction (X-direction) between the second side surface (26) and the element back surface (22).

### [Clause B7]

The semiconductor laser element according to clause B6, where
a length (LX1) of the first recess (60) in the first direction (X-direction) is greater than a length (RX1) of each first region (27) in the first direction (X-direction), and
a length (LX2) of the second recess (70) in the first direction (X-direction) is greater than a length (RX2) of each second region (28) in the first direction (X-direction).

### [Clause B8]

The semiconductor laser element according to clause B6, where
a ratio (LX1/LS) of a length (LX1) of the first recess (60) in the first direction (X-direction) to a length (LS) of the element body (20) in the first direction (X-direction) is greater than or equal to ⅝ and less than or equal to ⅞, and
a ratio (LX2/LS) of a length (LX2) of the second recess (70) in the first direction (X-direction) to a length (LS) of the element body (20) in the first direction (X-direction) is greater than or equal to ⅝ and less than or equal to ⅞.

### [Clause B9]

The semiconductor laser element according to any one of clauses B6 to B8, where
the first recess (60) includes first end connection surfaces (63A, 63B) arranged on opposite ends of the first recess (60) in the first direction (X-direction),
the second recess (70) includes second end connection surfaces (73A, 73B) arranged on opposite ends of the second recess (70) in the first direction (X-direction), and
an angle (θ2) of each of the first end connection surfaces (63A, 63B) relative to the first inner side surface (61) and an angle of each of the second end connection surfaces (73A, 73B) relative to the second inner side surface (71) are greater than an angle (θB) of the inclined surface of the first connection surface (62) relative to the first inner side surface (61) and an angle of the inclined surface of the second connection surface (72) relative to the second inner side surface (71), respectively.

### [Clause B10]

The semiconductor laser element according to clause B9, where
an angle (θ2) of each of the first end connection surfaces (63A, 63B) relative to the first inner side surface (61) is greater than or equal to 85° and less than or equal to 95°, and
an angle of each of the second end connection surfaces (73A, 73B) relative to the second inner side surface (71) is greater than or equal to 85° and less than or equal to 95°.

### [Clause B11]

The semiconductor laser element according to clause B9, where
an angle (θ2) of each of the first end connection surfaces (63A, 63B) relative to the first inner side surface (61) is greater than or equal to 87° and less than or equal to 93°, and
an angle of each of the second end connection surfaces (73A, 73B) relative to the second inner side surface (71) is greater than or equal to 87° and less than or equal to 93°.

### [Clause B12]

The semiconductor laser element according to clause B9, where
an angle (θ2) of each of the first end connection surfaces (63A, 63B) relative to the first inner side surface (61) is greater than or equal to 88° and less than or equal to 92°, and
an angle of each of the second end connection surfaces (73A, 73B) relative to the second inner side surface (71) is greater than or equal to 88° and less than or equal to 92°.

### [Clause B13]

The semiconductor laser element according to any one of clauses B6 to B8, where
the first recess (60) includes first end connection surfaces (63A, 63B) arranged on opposite ends of the first recess (60) in the first direction (X-direction),
the second recess (70) includes second end connection surfaces (73A, 73B) arranged on opposite ends of the second recess (70) in the first direction (X-direction), and
a length (LE) of each of the first end connection surfaces (63A, 63B) between the first inner side surface (61) and the first side surface (25) and a length of each of the second end connection surfaces (73A, 73B) between the second inner side surface (71) and the second side surface (26) are less than a length (LC) of the inclined surface of the first connection surface (62) in an inclination direction and a length of the inclined surface of the second connection surface (72) in an inclination direction, respectively.

### [Clause B14]

The semiconductor laser element according to clause B13, where
a length of each of the first end connection surfaces (63A, 63B) between the first inner side surface (61) and the first side surface (25) is greater than or equal to 1 μm and less than or equal to 5 μm, and
a length of each of the second end connection surfaces (73A, 73B) between the second inner side surface (71) and the second side surface (26) is greater than or equal to 1 μm and less than or equal to 5 μm.

### [Clause B15]

The semiconductor laser element according to any one of clauses B1 to B14, where
the element body (20) includes
   a semiconductor substrate (30) including a substrate back surface (32) including the element back surface (22) and a substrate front surface (31) facing away from the substrate back surface (32), and
   a semiconductor layer (40) arranged on the substrate front surface (31) and including a front surface (41) defining the element front surface (21) and an active layer (42) configured to emit the laser light,
the first recess (60) is arranged between the substrate back surface (32) and the first substrate side surface (35), and
the second recess (70) is arranged between the substrate back surface (32) and the second substrate side surface (36).

### [Clause B16]

The semiconductor laser element according to clause B15, where the semiconductor layer (40) includes
an n-type cladding layer (45A) arranged closer to the semiconductor substrate (30) than the active layer (42) is, and
a p-type cladding layer (46A, 46C) arranged at a side of the active layer (42) opposite from the n-type cladding layer (45A).

### [Clause B17]

The semiconductor laser element according to clause B15 or B16, where the semiconductor substrate (30) is composed of a GaAs substrate.

### [Clause B18]

The semiconductor laser element according to any one of clauses B15 to B17, where
the semiconductor substrate (30) includes
   a first substrate end surface (33) and a second substrate end surface (34) facing away from each other in the first direction (X-direction), and
   a first substrate side surface (35) and a second substrate side surface (36) facing away from each other in the second direction (Y-direction),
an angle of the first substrate side surface (35) relative to the substrate front surface (31) is 90°, and
an angle of the second substrate side surface (36) relative to the substrate front surface (31) is 90°.

### [Clause B19]

The semiconductor laser element according to any one of clauses B15 to B17, where
the semiconductor substrate (30) includes
   a first substrate end surface (33) and a second substrate end surface (34) facing away from each other in the first direction (X-direction), and
   a first substrate side surface (35) and a second substrate side surface (36) facing away from each other in the second direction (Y-direction),
the first substrate side surface (35) and the second substrate side surface (36) are each inclined relative to a direction (Z-direction) orthogonal to the substrate front surface (31), and
the first substrate side surface (35) and the second substrate side surface (36) are each inclined 10° relative to a direction (Z-direction) orthogonal to the substrate front surface (31).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

### REFERENCE SIGNS LIST

10) semiconductor laser element
20) element body
21) element front surface
22) element back surface
23) first end surface
24) second end surface
25) first side surface
26) second side surface
27) first region
28) second region
30) semiconductor substrate
31) substrate front surface
32) substrate back surface
33) first substrate end surface
34) second substrate end surface
35) first substrate side surface
36) second substrate side surface
40) semiconductor layer
41) front surface
42) active layer
43) n-side guide layer
44) p-side guide layer
45) n-type semiconductor layer
45A) n-type cladding layer
46) p-type semiconductor layer
46A) first p-type cladding layer
46B) first p-type etching stop layer
46C) second p-type cladding layer
46D) second p-type etching stop layer
46E) p-type cap layer
46F) p-type contact layer
47) ridge
48) current confinement layer
51) front electrode
52) back electrode
60) first recess
61) first inner side surface
62) first connection surface
62A) inclined surface
62B) flat surface
63A, 63B) first end connection surface
70) second recess
71) second inner side surface
72) second connection surface
73A, 73B) second end connection surface
200) semiconductor wafer
201) wafer front surface
202) wafer back surface
210) laser bar
211, 212) side surface
220) separation groove
221) first separation side surface
222) second separation side surface
223) first taper surface
224) second taper surface
230) separator
LC) length of first connection surface in inclination direction
LE) length of first end connection surface between first inner side surface and first side surface
LS) length of element body in X-direction
LX1) length of first recess in X-direction
LX2) length of second recess in X-direction
LZ1) length of first recess in Z-direction
LZC) length, in Z-direction, of portion of first inner side surface located closer to center than end portions in X-direction.
LZE) length, in Z-direction, of two ends of first inner side surface in X-direction
RX1) length of first region in X-direction
RX2) length of second region in X-direction
W1) distance between first side surface and first inner side surface in direction orthogonal to first side surface
θ1) angle of first connection surface relative to element front surface
θ2) angle of first end connection surface relative to first inner side surface
θ3) angle of first connection surface relative to element back surface
θ4) angle of first substrate side surface and second substrate side surface relative to a direction orthogonal to substrate front surface
θA) angle of first connection surface relative to first inner side surface
θB) angle of first connection surface relative to first inner side surface

1. A semiconductor laser element, comprising:
an element body including an element front surface and an element back surface that face away from each other, the element front surface facing in a thickness direction, a first end surface and a second end surface that face away from each other in a first direction as viewed in the thickness direction, and a first side surface and a second side surface that face away from each other in a second direction orthogonal to the first direction as viewed in the thickness direction, the element body being configured to emit laser light from the first end surface;
a front electrode formed on the element front surface; and
a back electrode formed on the element back surface, wherein
the element body includes
a first recess recessed into the element body between the first side surface and the element front surface, and
a second recess recessed into the element body between the second side surface and the element front surface,
the first recess includes a first inner side surface facing in the same direction as the first side surface and a first connection surface connecting the first inner side surface and the first side surface,
the second recess includes a second inner side surface facing in the same direction as the second side surface and a second connection surface connecting the second inner side surface and the second side surface, and
the first connection surface and the second connection surface each include an inclined surface inclined relative to the element front surface at an angle differing from those of the first side surface and the second side surface.

2. The semiconductor laser element according to claim 1, wherein an angle of the inclined surface of the first connection surface relative to the element front surface and an angle of the inclined surface of the second connection surface relative to the element front surface are each greater than or equal to 50° and less than or equal to 60°.

3. The semiconductor laser element according to claim 1, wherein a distance between the first side surface and the first inner side surface in a direction orthogonal to the first inner side surface and a distance between the second side surface and the second inner side surface in a direction orthogonal to the second inner side surface are each greater than or equal to 1 μm and less than or equal to 5 μm.

4. The semiconductor laser element according to claim 1, wherein a length of the inclined surface of the first connection surface in an inclination direction and a length of the inclined surface of the second connection surface in an inclination direction are each greater than or equal to 2 μm and less than or equal to 8 μm.

5. The semiconductor laser element according to claim 1, wherein each of the first recess and the second recess is partially arranged in the element body in the first direction.

6. The semiconductor laser element according to claim 5, wherein
the element body includes
first regions located at opposite ends of the element body in the first direction between the first side surface and the element front surface so that the first recess is not formed in the first regions, and
second regions located at opposite ends of the element body in the first direction between the second side surface and the element front surface so that the second recess is not formed in the second regions,
the first recess is a single first recess arranged between the first regions, which are located at opposite ends in the first direction between the first side surface and the element front surface, and
the second recess is a single second recess arranged between the second regions, which are located at opposite ends in the first direction between the second side surface and the element front surface.

7. The semiconductor laser element according to claim 6, wherein
a length of the first recess in the first direction is greater than a length of each first region in the first direction, and
a length of the second recess in the first direction is greater than a length of each second region in the first direction.

8. The semiconductor laser element according to claim 6, wherein
a ratio of a length of the first recess in the first direction to a length of the element body in the first direction is greater than or equal to ⅝ and less than or equal to ⅞, and
a ratio of a length of the second recess in the first direction to a length of the element body in the first direction is greater than or equal to ⅝ and less than or equal to ⅞.

9. The semiconductor laser element according to claim 6, wherein
the first recess includes first end connection surfaces arranged on opposite ends of the first recess in the first direction,
the second recess includes second end connection surfaces arranged on opposite ends of the second recess in the first direction, and
an angle of each of the first end connection surfaces relative to the first inner side surface and an angle of each of the second end connection surfaces relative to the second inner side surface are greater than an angle of the inclined surface of the first connection surface relative to the first inner side surface and an angle of the inclined surface of the second connection surface relative to the second inner side surface, respectively.

10. The semiconductor laser element according to claim 9, wherein
an angle of each of the first end connection surfaces relative to the first inner side surface is greater than or equal to 85° and less than or equal to 95°, and
an angle of each of the second end connection surfaces relative to the second inner side surface is greater than or equal to 85° and less than or equal to 95°.

11. The semiconductor laser element according to claim 9, wherein
an angle of each of the first end connection surfaces relative to the first inner side surface is greater than or equal to 87° and less than or equal to 93°, and
an angle of each of the second end connection surfaces relative to the second inner side surface is greater than or equal to 87° and less than or equal to 93°.

12. The semiconductor laser element according to claim 9, wherein
an angle of each of the first end connection surfaces relative to the first inner side surface is greater than or equal to 88° and less than or equal to 92°, and
an angle of each of the second end connection surfaces relative to the second inner side surface is greater than or equal to 88° and less than or equal to 92°.

13. The semiconductor laser element according to claim 6, wherein
the first recess includes first end connection surfaces arranged on opposite ends of the first recess in the first direction,
the second recess includes second end connection surfaces arranged on opposite ends of the second recess in the first direction, and
a length of each of the first end connection surfaces between the first inner side surface and the first side surface and a length of each of the second end connection surfaces between the second inner side surface and the second side surface are less than a length of the inclined surface of the first connection surface in an inclination direction and a length of the inclined surface of the second connection surface in an inclination direction, respectively.

14. The semiconductor laser element according to claim 13, wherein
a length of each of the first end connection surfaces between the first inner side surface and the first side surface is greater than or equal to 1 μm and less than or equal to 5 μm, and
a length of each of the second end connection surfaces between the second inner side surface and the second side surface is greater than or equal to 1 μm and less than or equal to 5 μm.

15. The semiconductor laser element according to claim 1, wherein
the element body includes
a semiconductor substrate including a substrate back surface including the element back surface and a substrate front surface facing away from the substrate back surface, and
a semiconductor layer arranged on the substrate front surface and including a front surface defining the element front surface and an active layer configured to emit the laser light, and
the first recess and the second recess extend from the semiconductor layer to the semiconductor substrate.

16. The semiconductor laser element according to claim 15, wherein the semiconductor layer includes
an n-type cladding layer arranged closer to the semiconductor substrate than the active layer is, and
a p-type cladding layer arranged at a side of the active layer opposite from the n-type cladding layer.

17. The semiconductor laser element according to claim 15, wherein the semiconductor substrate is composed of a GaAs substrate.

18. The semiconductor laser element according to claim 15, wherein
the semiconductor substrate includes
a first substrate end surface and a second substrate end surface facing away from each other in the first direction, and
a first substrate side surface and a second substrate side surface facing away from each other in the second direction,
an angle of the first substrate side surface relative to the substrate front surface is 90°, and
an angle of the second substrate side surface relative to the substrate front surface is 90°.

19. The semiconductor laser element according to claim 15, wherein
the semiconductor substrate includes
a first substrate end surface and a second substrate end surface facing away from each other in the first direction, and
a first substrate side surface and a second substrate side surface facing away from each other in the second direction,
the first substrate side surface and the second substrate side surface are each inclined relative to a direction orthogonal to the substrate front surface, and
the first substrate side surface and the second substrate side surface are each inclined 10° relative to a direction orthogonal to the substrate front surface.
